(19) United States
(12) Patent Application Publication
(10) Pub. No.: US 2024/0395839 A1
(43) Pub. Date: Nov. 28, 2024

(54) PHOTOELECTRIC CONVERSION DEVICE AND IMAGING SYSTEM

(71) Applicant: CANON KABUSHIKI KAISHA, Tokyo (JP)

(72) Inventors: HIDEO KOBAYASHI, Tokyo (JP); SO HASEGAWA, Kanagawa (JP)

(21) Appl. No.: 18/504,387

(22) Filed: Nov. 8, 2023

(30) Foreign Application Priority Data
Nov. 18, 2022 (JP) 2022-184524

(51) Int. Cl. H01L 27/146; H04N 25/772

(52) U.S. Cl. CPC H01L 27/14623; H01L 27/14636; H04N 25/772

(57) ABSTRACT

A photoelectric conversion device includes a pixel array unit including pixels, column circuits provided corresponding to columns of the pixel array unit, and signal lines for supplying signals to the column circuits. The pixel array unit includes a first region that is provided with a pixel including a photoelectric conversion unit and to which light is incident and a second region that is provided with a pixel including no photoelectric conversion units and is shielded from light, and wherein the first and second region are defined by columns. The signal lines include a first signal line connected to a column circuit corresponding to the first region and not connected to a column circuit corresponding to the second region, and a second signal line connected to the column circuit corresponding to the second region and not connected to the column circuit corresponding to the first region.

### BACKGROUND OF THE INVENTION

### Field of the Invention

The present invention relates to a photoelectric conversion device and an imaging system.

### Description of the Related Art

In a photoelectric conversion device such as a CMOS image sensor, a pixel shielded from light (light-shielded pixel) may be provided in addition to a pixel which outputs a signal corresponding to an amount of incident light in order to acquire a signal for correcting a noise component due to a dark current component of a pixel, a power supply fluctuation, or the like. Japanese Patent Application Laid-Open No. 2020-017916 discloses an imaging device including in a pixel array unit a region where a pixel including a photoelectric conversion unit is disposed and light is incident, a region where a pixel including a photoelectric conversion unit is disposed and light is shielded, and a region where a pixel including no photoelectric conversion unit is disposed and light is shielded.

According to the imaging device described in Japanese Patent Application Laid-Open No. 2020-017916, it is possible to reduce a shading caused by a dark current component of pixels or an in-plane distribution thereof and unevenness in stripes caused by a power supply fluctuation. However, the technology described in Japanese Patent Application Laid-Open No. 2020-017916 may not necessarily be preferable from the viewpoint of power saving and high accuracy of correction.

### SUMMARY OF THE INVENTION

An object of the present invention is to provide a technique for realizing power saving and high precision correction in a photoelectric conversion device and an imaging system having a function of correcting a noise component using a signal of a light-shielded pixel.

According to an embodiment of the present disclosure, there is provided a photoelectric conversion device including a pixel array unit including a plurality of pixels arranged to form a plurality of columns, a plurality of column circuits provided corresponding to each of the plurality of columns and to which a pixel signal output from a pixel of the corresponding column is input, and a plurality of signal lines configured to supply signals to the plurality of column circuits, wherein the pixel array unit includes a first region that is provided with a pixel including a photoelectric conversion unit and to which light is incident, and a second region that is provided with a pixel including no photoelectric conversion units and is shielded from light, wherein the first region and the second region are defined by columns, and wherein the plurality of signal lines includes a first signal line connected to a column circuit corresponding to a column of the first region and not connected to a column circuit corresponding to a column of the second region, and a second signal line connected to the column circuit corresponding to the column of the second region and not connected to the column circuit corresponding to the column of the first region.

According to another embodiment of the present disclosure, there is provided a photoelectric conversion device including a pixel array unit including a plurality of pixels arranged to form a plurality of columns, a plurality of column circuits provided corresponding to each of the plurality of columns and to which a pixel signal output from a pixel of the corresponding column is input, and a plurality of signal lines configured to supply signals to the plurality of column circuits, wherein the pixel array unit includes a first region that is provided with a pixel including a photoelectric conversion unit and to which light is incident, a second region that is provided with a pixel including no photoelectric conversion units and is shielded from light, and a third region that is provided with a pixel including a photoelectric conversion unit and is shielded from light, wherein the first region, the second region and the third region are defined by columns, and wherein the plurality of signal lines includes a first signal line connected to a column circuit corresponding to a column of the third region and not connected to a column circuit corresponding to a column of the second region, and a second signal line connected to the column circuit corresponding to the column of the second region and not connected to the column circuit corresponding to the column of the third region.

Further features of the present invention will become apparent from the following description of exemplary embodiments with reference to the attached drawings.

### BRIEF DESCRIPTION OF THE DRAWINGS

FIG. 1 is a block diagram illustrating a schematic configuration of a photoelectric conversion device according to a first embodiment of the present invention.

FIG. 2 and FIG. 3 are circuit diagrams illustrating a configuration example of a pixel in the photoelectric conversion device according to the first embodiment of the present invention.

FIG. 4 and FIG. 5 are circuit diagrams illustrating a configuration example of a column circuit in the photoelectric conversion device according to the first embodiment of the present invention.

FIG. 6A and FIG. 6B are schematic diagrams illustrating a configuration example of the photoelectric conversion device according to the first embodiment of the present invention.

FIG. 7 is a circuit diagram illustrating a configuration example of a column circuit in a photoelectric conversion device according to a second embodiment of the present invention.

FIG. 8 is a timing chart illustrating a method of driving the photoelectric conversion device according to the second embodiment of the present invention.

FIG. 9 is a circuit diagram illustrating a configuration example of a column circuit in a photoelectric conversion device according to a third embodiment of the present invention.

FIG. 10 is a timing chart illustrating a method of driving the photoelectric conversion device according to the third embodiment of the present invention.

FIG. 11 is a circuit diagram illustrating a configuration example of a column circuit in a photoelectric conversion device according to a fourth embodiment of the present invention.

FIG. 12 is a circuit diagram illustrating a configuration example of a switching unit in the photoelectric conversion device according to the fourth embodiment of the present invention.

FIG. 13 is a timing chart illustrating a method of driving the photoelectric conversion device according to the fourth embodiment of the present invention.

FIG. 14 is a circuit diagram illustrating a configuration example of a column circuit in a photoelectric conversion device according to a modification of the fourth embodiment of the present invention.

FIG. 15 is a circuit diagram illustrating a configuration example of a column circuit in a photoelectric conversion device according to a fifth embodiment of the present invention.

FIG. 16 is a block diagram illustrating a schematic configuration of an imaging system according to a sixth embodiment of the present invention.

FIG. 17A is a diagram illustrating a configuration example of an imaging system according to a seventh embodiment of the present invention.

FIG. 17B is a diagram illustrating a configuration example of a movable object according to the seventh embodiment of the present invention.

FIG. 18 is a block diagram illustrating a schematic configuration of equipment according to an eighth embodiment of the present invention.

### DESCRIPTION OF THE EMBODIMENTS

Preferred embodiments of the present invention will now be described in detail in accordance with the accompanying drawings.

### First Embodiment

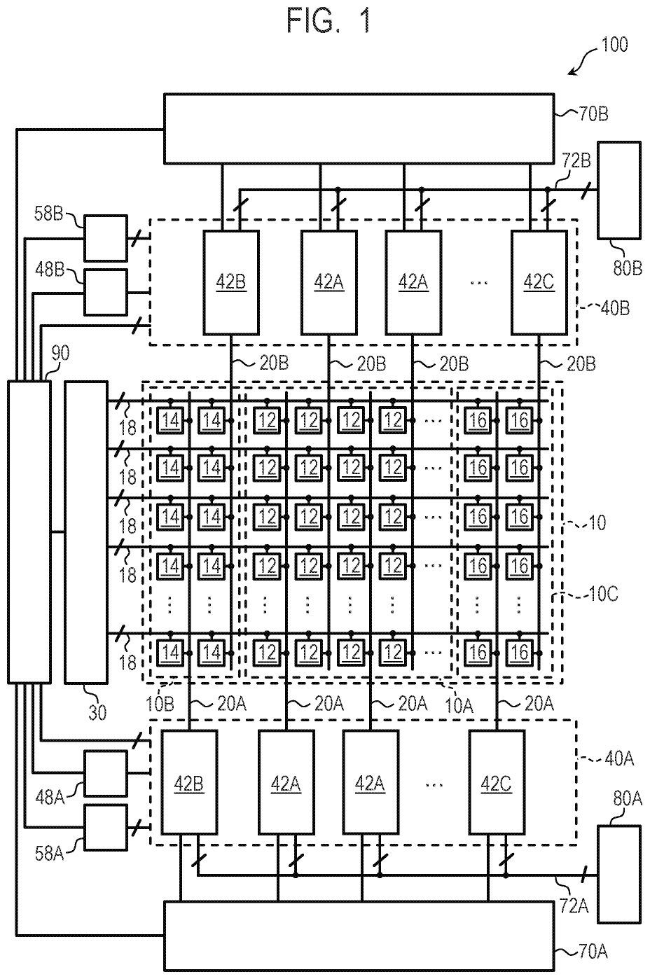

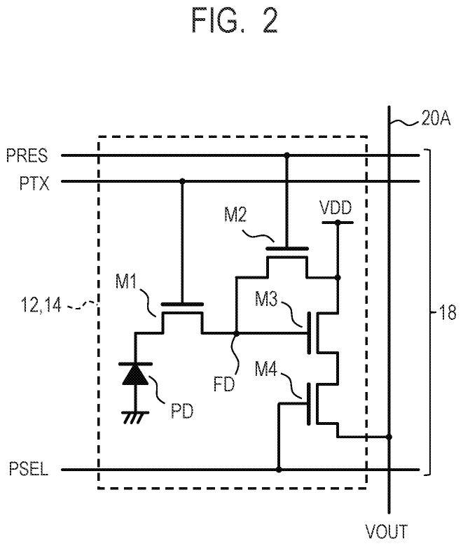

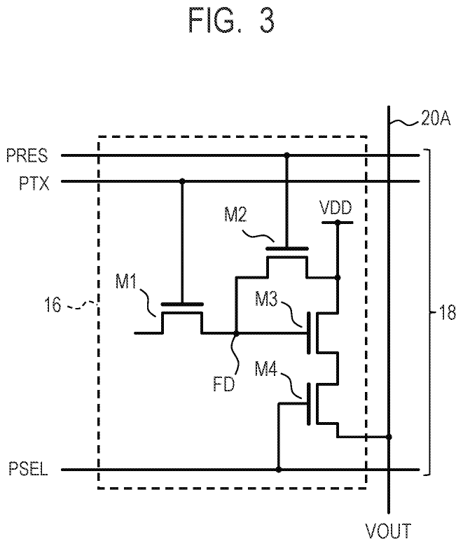

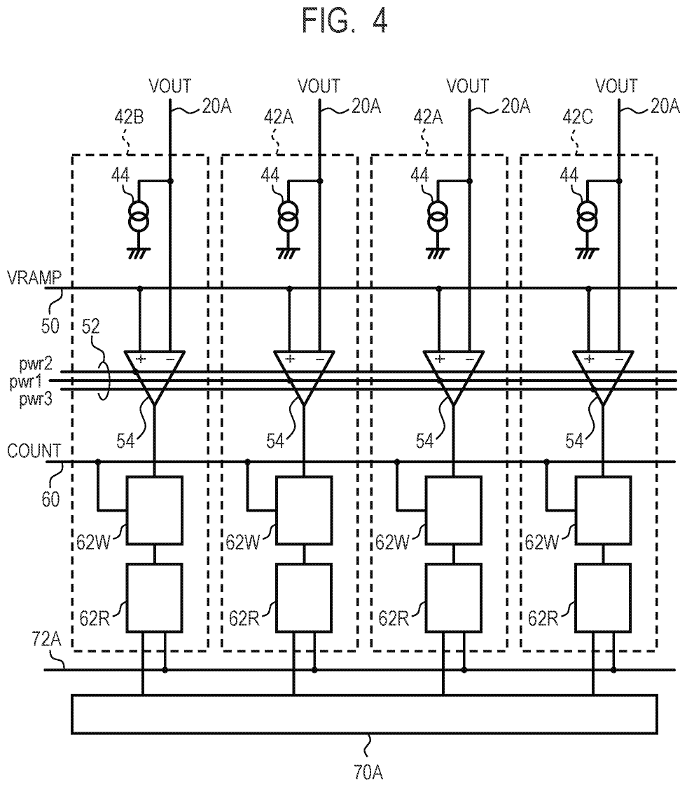

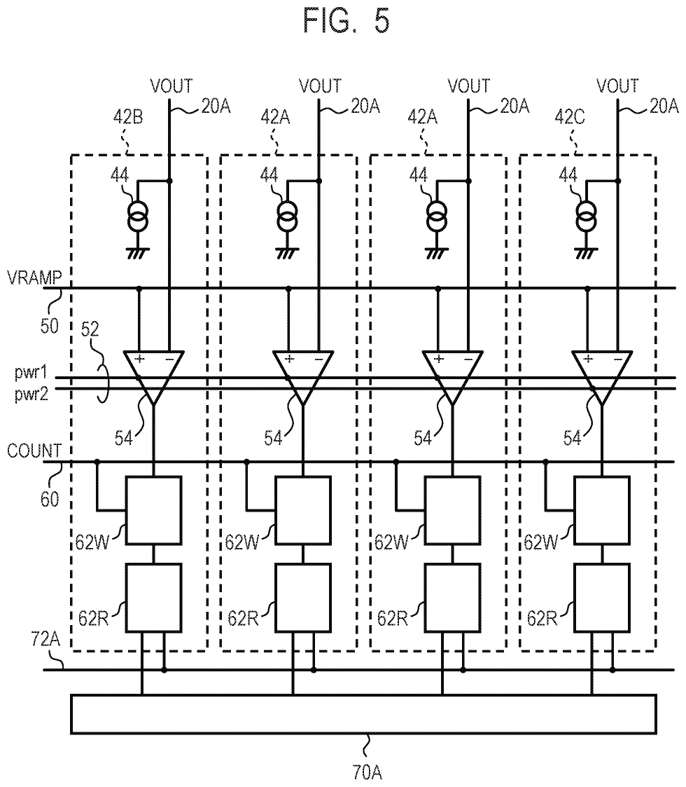

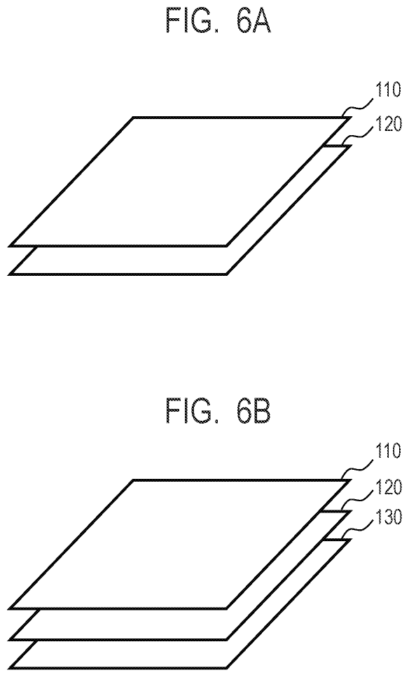

A photoelectric conversion device and a method of driving the same according to a first embodiment of the present invention will be described with reference to FIG. 1 to FIG. 6B. FIG. 1 is a block diagram illustrating a schematic configuration of a photoelectric conversion device according to the present embodiment. FIG. 2 and FIG. 3 are circuit diagrams illustrating a configuration example of a pixel in the photoelectric conversion device according to the present embodiment. FIG. 4 and FIG. 5 are circuit diagrams illustrating a configuration example of a column circuit in the photoelectric conversion device according to the present embodiment. FIG. 6A and FIG. 6B are schematic diagrams illustrating a configuration example of the photoelectric conversion device according to the present embodiment.

As illustrated in FIG. 1, the photoelectric conversion device 100 according to the present embodiment includes a pixel array unit 10, a vertical scanning circuit 30, readout circuits 40A and 40B, reference signal generation circuits 48A and 48B, and counter circuits 58A and 58B. The photoelectric conversion device 100 further includes horizontal scanning circuits 70A and 70B, output circuits 80A and 80B, and a control circuit 90.

The pixel array unit 10 includes a plurality of pixels 12, 14, and 16 arranged in a matrix form over a plurality of rows and a plurality of columns. The pixel array unit 10 includes regions 10A, 10B, and 10C defined by columns. The number of rows constituting the pixel array unit 10 and the number of columns included in each of the regions 10A, 10B, and 10C are not particularly limited.

A plurality of pixels 12 are arranged in the region 10A, a plurality of pixels 14 are arranged in the region 10B, and a plurality of pixels 16 are arranged in the region 10C. The pixel 12 includes a photoelectric conversion unit formed of a photoelectric conversion element such as a photodiode, and a readout circuit for reading out a signal from the photoelectric conversion unit, and has a role of outputting a signal corresponding to an amount of incident light. Similarly to the pixel 12, the pixel 14 includes a photoelectric conversion unit and a readout circuit, but is shielded from light, and has a role of outputting a signal corresponding to a dark current of the photoelectric conversion element. The pixel 16 includes a readout circuit similar to the pixels 12 and 14, does not include a photoelectric conversion unit, is shielded from light, and has a role of outputting a signal including a noise caused by a constituent element of the readout circuit. Note that although the pixels 14 and 16 are not an element generating a signal for forming an image strictly, they include circuit elements common to the pixel 12, and thus are referred to as “pixel” for convenience in this specification. A specific configuration of the pixels 12, 14, and 16 will be described later.

In each row of the pixel array unit 10, a control line 18 is arranged so as to extend in a first direction (lateral direction in FIG. 1). Each of the control lines 18 is connected to each of the pixels 12, 14, and 16 arranged in the first direction on the corresponding row, and forms a common signal line for these pixels 12, 14, and 16. The first direction in which the control lines 18 extend may be referred to as a row direction or a horizontal direction. The control line 18 is connected to the vertical scanning circuit 30. The control lines 18 in each row may include a plurality of signal lines.

In each column of the pixel array unit 10, a vertical output line 20A or a vertical output line 20B is arranged so as to extend in a second direction (vertical direction in FIG. 1) intersecting with the first direction. The vertical output lines 20A and the vertical output lines 20B are alternately arranged in each column. For example, the vertical output lines 20A are arranged in odd-numbered columns, and the vertical output lines 20B are arranged in even-numbered columns. Each of the vertical output lines 20A and 20B is connected to the pixels 12, the pixels 14, or the pixels 16 arranged in the second direction on the corresponding column, and forms a signal line common to these pixels 12, these pixels 14, or these pixels 16. The second direction in which the vertical output lines 20A and 20B extend may be referred to as a column direction or a vertical direction. The vertical output line 20A is connected to the readout circuit 40A. The vertical output line 20B is connected to the readout circuit 40B.

The vertical scanning circuit 30 is a control circuit having a function of receiving a control signal from the control circuit 90, generating a control signal for driving the pixels 12, 14, 16 and outputting the generated control signal to the pixels 12, 14, 16 via the control line 18. A logic circuit such as a shift register or an address decoder may be used as the vertical scanning circuit 30. The vertical scanning circuit 30 sequentially outputs control signals to the control lines 18 of each row, and sequentially drives the pixels 12, 14, and 16 of the pixel array unit 10 in units of rows. The signals read out from the pixels 12, 14, and 16 in units of rows are input to the readout circuit 40A or the readout circuit 40B via the vertical output lines 20A or the vertical output lines 20B arranged in each column of the pixel array unit 10.

The readout circuit 40A includes a plurality of column circuits 42 corresponding to the number of columns in which the vertical output lines 20A are arranged. In FIG. 1, the plurality of column circuits 42 forming the readout circuit 40A is labelled as 42A for the column circuits 42 provided corresponding to the columns of the region 10A, labelled as 42B for the column circuits 42 provided corresponding to the columns of the region 10B, and labelled as 42C for the column circuit 42 provided corresponding to the columns of the region 10C. Each of the column circuits 42A, 42B, and 42C of the readout circuit 40A is connected to the vertical output line 20A of the corresponding column. Similarly, the readout circuit 40B includes a plurality of column circuits 42 corresponding to the number of columns in which the vertical output lines 20B are arranged. In FIG. 1, the plurality of column circuits 42 forming the readout circuit 40B is labelled as 42A for the column circuits 42 provided corresponding to the columns of the region 10A, labelled as 42B for the column circuits 42 provided corresponding to the columns of the region 10B, and labelled as 42C for the column circuit 42 provided corresponding to the columns of the region 10C. Each of the column circuits 42A, 42B, and 42C of the readout circuit 40B is connected to the vertical output line 20B of the corresponding column.

The column circuit 42A is a processing circuit that performs predetermined processing on the pixel signal read out from the pixel 12 in the corresponding columns. The column circuit 42B is a processing circuit that performs predetermined processing on the pixel signal read out from the pixel 14 in the corresponding columns. The column circuit 42C is a processing circuit that performs predetermined processing on the pixel signal read out from the pixel 16 in the corresponding columns. Examples of the processing performed by the column circuits 42A, 42B, and 42C include signal processing such as an amplification processing and an AD conversion (analog-to-digital conversion) processing. The column circuits 42A, 42B, and 42C include a signal holding circuit (memory) for holding the processed pixel signal. In the following description, when the column circuits 42A, 42B, and 42C are described in common, the distinction among A, B, and C may be omitted and may be referred to as a column circuit 42.

The reference signal generation circuit 48A is connected to the readout circuit 40A. The reference signal generation circuit 48A has a function of receiving a control signal from the control circuit 90, generating a reference signal for use in the AD conversion, and outputting the reference signal to the readout circuit 40A. Similarly, the reference signal generation circuit 48B is connected to the readout circuit 40B. The reference signal generation circuit 48B has a function of receiving a control signal from the control circuit 90, generating a reference signal for use in the AD conversion, and outputting the reference signal to the readout circuit 40B.

The reference signal for use in the AD conversion may be a signal having a predetermined amplitude corresponding to the range of the pixel signal and whose signal level changes with time. The reference signal is not particularly limited, but, for example, a ramp signal whose signal level monotonically increases or monotonically decreases with lapse of time may be applied. It is to be noted that the change of the signal level is not necessarily continuous, and may be in a step shape. The change in the signal level need not necessarily be linear with respect to time, but may be curvilinear with respect to time (e.g., sine wave or cosine wave).

The counter circuit 58A is connected to the readout circuit 40A. The counter circuit 58A performs a counting operation in response to a control signal from the control circuit 90, and outputs a count signal indicating the count value to the readout circuit 40A. The counter circuit 58A starts a counting operation in synchronization with a timing at which a change in the signal level of the reference signal supplied from the reference signal generation circuit 48A starts. Similarly, the counter circuit 58B is connected to the readout circuit 40B. The counter circuit 58B has a function of performing a counting operation in response to a control signal from the control circuit 90 and outputting a count signal indicating the count value to the readout circuit 40B. The counter circuit 58B starts a counting operation in synchronization with a timing at which a change in the signal level of the reference signal supplied from the reference signal generation circuit 48B starts.

The horizontal scanning circuit 70A is a control circuit having a function of receiving a control signal from the control circuit 90, generating a control signal for reading out pixel signals from the column circuits 42A, 42B, and 42C of the readout circuit 40A, and outputting the generated control signal to the readout circuit 40A. The horizontal scanning circuit 70A sequentially scans the column circuits 42A, 42B, and 42C of the readout circuit 40A, and sequentially outputs the pixel signals held in the column circuits 42A, 42B, and 42C to the output circuit 80A via the horizontal output line 72A. Similarly, the horizontal scanning circuit 70B is a control unit having a function of receiving a control signal from the control circuit 90, generating a control signal for reading out pixel signals from the column circuits 42A, 42B, and 42C of the readout circuit 40B, and outputting the generated control signal to the readout circuit 40B. The horizontal scanning circuit 70B sequentially scans the column circuits 42A, 42B, and 42C of the readout circuit 40B, and sequentially outputs the pixel signals held in the column circuits 42A, 42B, and 42C to the output circuit 80B via the horizontal output line 72B. A logic circuit such as a shift register or an address decoder may be used for the horizontal scanning circuits 70A and 70B.

The output circuit 80A is a processing circuit that performs predetermined signal processing on the pixel signals in the column selected by the horizontal scanning circuit 70A and outputs the processed pixel data, and may be formed of a buffer amplifier, a differential amplifier, or the like. Similarly, the output circuit 80B is a processing circuit that performs predetermined signal processing on the pixel signals in the columns selected by the horizontal scanning circuit 70B and outputs the processed pixel data, and may be formed of a buffer amplifier, a differential amplifier, or the like. Examples of the signal processing performed by the output circuits 80A and 80B include a correction processing by CDS (correlated double sampling) and an amplification processing.

The control circuit 90 is a control circuit for generating control signals for controlling operations of the vertical scanning circuit 30, the readout circuits 40A and 40B, the reference signal generation circuits 48A and 48B, the counter circuits 58A and 58B, and the horizontal scanning circuits 70A and 70B, and outputting the generated control signals to the respective functional blocks. At least a part of the control signals for controlling the operations of the vertical scanning circuit 30, the readout circuits 40A and 40B, the reference signal generation circuits 48A and 48B, the counter circuits 58A and 58B, and the horizontal scanning circuits 70A and 70B may be supplied from the outside of the photoelectric conversion device 100.

FIG. 1 illustrates an example in which two readout circuit blocks including a readout circuit block including a readout circuit 40A, a horizontal scanning circuit 70A, an output circuit 80A, and the like, and a readout circuit block including a readout circuit 40B, a horizontal scanning circuit 70B, an output circuit 80B, and the like are provided. However, the number of readout circuit blocks is not necessarily two, but may be one.

As illustrated in FIG. 2, for example, each of the pixels 12 and the pixels 14 constituting the pixel array unit 10 may include a photoelectric conversion element PD, a transfer transistor M1, a reset transistor M2, an amplifier transistor M3, and a select transistor M4. The pixel 14 is the same as the pixel 12 except that it is shielded by a light shielding layer (not illustrated).

The photoelectric conversion element PD is, for example, a photodiode, an anode of which is connected to a ground voltage node, and a cathode of which is connected to a source of the transfer transistor M1. A drain of the transfer transistor M1 is connected to a source of the reset transistor M2 and a gate of the amplifier transistor M3. A node FD to which the drain of the transfer transistor M1, the source of the reset transistor M2, and the gate of the amplifier transistor M3 are connected is a so-called floating diffusion. The floating diffusion includes a capacitance component (floating diffusion capacitance) and functions as a charge holding portion. The floating diffusion capacitance may include a p-n junction capacitance and an interconnection capacitance. A drain of the reset transistor M2 and a drain of the amplifier transistor M3 are connected to a node to which a power supply voltage (voltage VDD) is supplied. A source of the amplifier transistor M3 is connected to a drain of the select transistor M4. A source of the select transistor M4 is connected to the vertical output line 20A (or the vertical output line 20B).

In the case of the pixel configuration of FIG. 2, the control line 18 of each row includes three signal lines including a signal line connected to a gate of the transfer transistor M1, a signal line connected to a gate of the reset transistor M2, and a signal line connected to a gate of the select transistor M4. A control signal PTX is supplied from the vertical scanning circuit 30 to the gate of the transfer transistor M1. A control signal PRES is supplied from the vertical scanning circuit 30 to the gate of the reset transistor M2. A control signal PSEL is supplied from the vertical scanning circuit 30 to the gate of the select transistor M4. When each transistor is formed of an n-channel MOS transistor, when a high-level control signal is supplied from the vertical scanning circuit 30, the corresponding transistor is turned on. When a low-level control signal is supplied from the vertical scanning circuit 30, the corresponding transistor is turned off.

In the present embodiment, a description will be given assuming a case where electrons are used as signal charge among electron-hole pairs generated in the photoelectric conversion element PD by light incidence. When electrons are used as the signal charge, each transistor of the pixels 12 and 14 may be formed of an n-channel MOS transistor. However, the signal charge is not limited to electrons, and holes may be used as the signal charge. When holes are used as the signal charge, the conductivity type of each transistor may be opposite to that described in the present embodiment. In addition, the term “source” or “drain” of the MOS transistor may vary depending on the conductivity type of the transistor or a function focusing on. Some or all of names of the source and the drain used in the present embodiment are sometimes referred to as reverse names.

The photoelectric conversion element PD converts (photoelectrically converts) incident light into charge of an amount corresponding to an amount of the incident light, and accumulates the generated charge. The transfer transistor M1 transfers the charge held in the photoelectric conversion element PD to the node FD by turning on. The charge transferred from the photoelectric conversion element PD is held in the capacitance (floating diffusion capacitance) of the node FD. As a result, the node FD becomes a potential corresponding to the amount of charge transferred from the photoelectric conversion element PD by the charge-voltage conversion by the floating diffusion capacitance.

The select transistor M4 connects the amplifier transistor M3 to the vertical output line 20A (or the vertical output line 20B) by turning on. The amplifier transistor M3 is configured such that a voltage VDD is supplied to the drain and a bias current is supplied from a current source (a current source 44 described later) (not illustrated) to the source via a select transistor M4, and constitutes an amplifier unit (source follower circuit) having the gate as an input node. Accordingly, the amplifier transistor M3 outputs a signal based on the voltage of the node FD to the vertical output line 20A (or the vertical output line 20B) via the select transistor M4. In this sense, the amplifier transistor M3 and the select transistor M4 forms an output unit that outputs a pixel signal corresponding to the amount of charge held in the node FD.

The reset transistor M2 has a function of controlling supply of a voltage (voltage VDD) for resetting the node FD serving as a charge holding portion to the node FD. The reset transistor M2 resets the node FD to a voltage corresponding to the voltage VDD by turning on.

As described above, the pixel 14 is a light-shielded pixel in which the photoelectric conversion element PD is shielded from light. Although the pixel 14 is shielded from light, the pixel 14 includes the photoelectric conversion element PD, so that it is possible to acquire a dark current component of the photoelectric conversion element PD from an output signal of the photoelectric conversion element PD. Therefore, by correcting an output signal of the pixel 12 using the output signal of the pixel 14, the dark current component may be removed from the output signal of the pixel 12.

As illustrated in FIG. 3, for example, each of the pixels 16 constituting the pixel array unit 10 may be configured by a transfer transistor M1, a reset transistor M2, an amplifier transistor M3, and a select transistor M4. The connection between these components in the pixel 16 is similar to that in the pixels 12 and 14. The source of the transfer transistor M1 may be configured to be floating or connectable to a predetermined voltage node. The pixel 16 is different from the pixel 12 and the pixel 14 in that the pixel 16 does not include the photoelectric conversion element PD. The pixel 16 is shielded from light by a not-illustrated light shielding layer, and is different from the pixel 12 and similar to the pixel 14 in this point.

Since the pixel 16 does not include the photoelectric conversion element PD, the dark current component of the photoelectric conversion element PD cannot be acquired from the pixel 16. However, since the photoelectric conversion element PD is not provided, there is an advantage that a correction signal of a noise component other than a dark current can be obtained with high accuracy without being affected by a pixel having a specifically large dark current component (white spot pixel). For example, the power supply voltage (voltage VDD) supplied to the drain of the reset transistor M2 and the drain of the amplifier transistor M3 may include a power supply noise caused by elements for generating the power supply voltage. When the power supply noise is coupled to the node FD via a parasitic capacitance (for example, gate-drain capacitance of the amplifier transistor M3), a noise of a horizontal stripe shape may be superimposed on the acquired image. The horizontal stripe noise can be reduced by detecting the horizontal stripe noise component by the pixel 16 and correcting the output signal of the pixel 12 using the output signal of the pixel 16.

Each of the column circuits 42A, 42B, and 42C constituting the readout circuit 40A may be formed of a current source 44, a comparison circuit 54, and memories 62W and 62R, for example, as illustrated in FIG. 4. The comparison circuit 54 includes two input nodes (a non-inverting input node (+) and an inverting input node (−)) to which two signals to be compared are input, and one output node to which a signal indicating a comparison result is output, and may be configured by, for example, a differential amplifier circuit. The memory 62W includes two input nodes and one output node. The memory 62R includes two input nodes and one output node.

The vertical output line 20A is connected to the current source 44 and one input node (inverting input node) of the comparison circuit 54 of the column circuit 42 of the corresponding column. The current source 44 serves as a load current source of the amplifier transistor M3 of the pixels 12, 14, and 16. A signal VOUT is input from the vertical output line 20A to the one input node of the comparison circuit 54. The other input node (non-inverting input node) of the comparison circuit 54 is connected to a reference signal line 50. The reference signal VRAMP is input from the reference signal generation circuit 48A to the other input node of the comparison circuit 54 via the reference signal line 50.

One input node of the memory 62W is connected to the output node of the comparison circuit 54. The other input node of the memory 62W is connected to a count signal line 60. A count signal COUNT is input from the counter circuit 58A to the other input node of the memory 62W via the count signal line 60. One input node of the memory 62R is connected to the output node of the memory 62W. The other input node of the memory 62R is connected to the horizontal scanning circuit 70A. The output node of the memory 62R is connected to the horizontal output line 72A.

The comparison circuit 54 compares a level of the signal VOUT supplied from the vertical output line 20A with a level of the reference signal VRAMP supplied from the reference signal line 50, and outputs a signal according to the comparison result. For example, the comparison circuit 54 outputs a high-level signal when the level of the reference signal VRAMP is lower than the level of the signal VOUT. The comparison circuit 54 outputs a low-level signal when the level of the reference signal VRAMP is higher than the level of the signal VOUT. The relationship between the relationship of the magnitude of the input signals and the level of the output signal may be reversed.

The memory 62W holds a count value indicated by the count signal COUNT supplied from the counter circuit 58A at a timing when the level of the output node of the comparison circuit 54 is inverted, as digital data of the pixel signal. The memory 62R holds the digital data of the pixel signal transferred from the memory 62W. The digital data held in the memory 62R is sequentially transferred to the output circuit 80A via the horizontal output line 72A for each column according to a control signal supplied from the horizontal scanning circuit 70A. By disposing the memory 62R on the post stage of the memory 62W, the AD conversion operation may be performed in parallel with the transfer operation to the output circuit 80A.

Instead of providing the counter circuit 58A, the memory 62W of the column circuit 42 may have a function of a counter circuit. In this case, the memory 62W of the column circuit 42 of each column receives the common clock signal output from the control circuit 90 and counts pulses of the clock signal. The count value at a timing when the level of the output signal of the comparison circuit 54 is inverted becomes digital data held in the memory 62W.

The column circuits 42A, 42B, and 42C of the readout circuit 40B are the same as the column circuits 42A, 42B, and 42C of the readout circuit 40A except that the column circuits 42A, 42B, and 42C of the readout circuit 40B are arranged in the columns different from the columns in which the column circuits 42A, 42B, and 42C of the readout circuit 40A are arranged, so that the explanations thereof are omitted here. Hereinafter, the column circuits 42A, 42B, and 42C of the readout circuit 40A will be described, but the same applies to the column circuits 42A, 42B, and 42C of the readout circuit 40B. In the following description, when the readout circuits 40A and 40B, the reference signal generation circuits 48A and 48B, and the like are described in common, the distinction between A and B is omitted, and the readout circuits 40 and the reference signal generation circuits 48, and the like may be referred to as a readout circuit.

Here, in the photoelectric conversion device according to the present embodiment, as illustrated in FIG. 4, different control lines are arranged in the comparison circuit 54 of the column circuit 42A, the comparison circuit 54 of the column circuit 42B, and the comparison circuit 54 of the column circuit 42C. That is, a control signal pwr1 is supplied from the control circuit 90 to the column circuits 42A of each column corresponding to the region 10A via the control line 52. A control signal pwr2 is supplied from the control circuit 90 to the column circuits 42B of each column corresponding to the region 10B via the control line 52. A control signal pwr3 is supplied from the control circuit 90 to the column circuits 42C of each column corresponding to the region 10C via the control line 52.

The control signals pwr1, pwr2, and pwr3 may be, for example, control signals for controlling a switch (not illustrated) that switches a conduction and a disconnection of a current path of the comparison circuit 54. For example, when the comparison circuit 54 is configured by a differential amplifier circuit, the control signals pwr1, pwr2, and pwr3 may be a control signal of a switch that switches a conduction and a disconnection of a tail current source, or a control signal that controls a current value flowing through the tail current source.

By configuring the comparison circuits 54 of the column circuits 42A, 42B, and 42C in this manner, the operation of the readout circuit 40 may be optimized according to the situation. For example, when the horizontal stripe noise correction using the output signal of the pixel 16 is not performed, the current consumption of the comparison circuit 54 of the column circuits 42A and 42B is not reduced, and the current consumption of the comparison circuit 54 of the column circuit 42C is reduced, whereby power saving can be achieved. Further, in the case of emphasizing high image quality, in order to perform correction processing using the output signals of the pixels 14 and 16, in addition to the comparison circuits 54 of the column circuits 42A, the comparison circuits 54 of the column circuits 42B and 42C may be in an operating state. Further, in the case of emphasizing low power, the current consumption of the comparison circuits 54 of the column circuits 42A is kept unchanged, and the comparison circuits 54 of the column circuits 42B and 42C may be kept in a state of reducing the current consumption. Further, although the low power is important, when the accumulation time is long and the dark current component is large, the current consumption of the comparison circuits 54 of the column circuits 42A and 42B is kept unchanged, and the comparison circuits 54 of the column circuits 42C may be kept in a state where the current consumption is reduced.

Although different control lines are arranged in the comparison circuits 54 of the column circuits 42A, 42B, and 42C in the configuration example of FIG. 4, different control lines may be arranged in the comparison circuits 54 of the column circuits 42A and 42B and the comparison circuits 54 of the column circuits 42C, for example, as illustrated in FIG. 5. For example, a control signal pwr1 is supplied from the control circuit 90 to the column circuits 42A and 42B of each column corresponding to the regions 10A and 10B via the control line 52. A control signal pwr2 is supplied from the control circuit 90 to the column circuits 42C of each column corresponding to the region 10C via the control line 52.

In the case of the configuration example of FIG. 5, variations in operation are reduced as compared with the case of the configuration example of FIG. 4, but power consumption can be reduced by setting the comparison circuits 54 of the column circuits 42C in a low current consumption state. The configuration example of FIG. 5 has an advantage in that the number of signal lines for supplying the control signals to the comparison circuits 54 can be reduced as compared with the configuration example of FIG. 4.

The photoelectric conversion device 100 according to the present embodiment may have a configuration in which all the circuit blocks described above are arranged on one substrate, or may have a configuration in which the circuit blocks are separately formed on each substrate as a stacked type in which a plurality of substrates are stacked.

FIG. 6A is a schematic diagram of a case where a pixel substrate 110 in which the pixel array unit 10 is disposed and a circuit substrate 120 in which other circuit blocks are disposed are stacked. By disposing the pixel substrate 110 and the circuit substrate 120 on different substrates, the size of the photoelectric conversion device 100 can be reduced without sacrificing the area of the pixel array unit 10.

FIG. 6B is a schematic diagram of a case where the pixel substrate 110 in which the pixel array unit 10 is disposed and the circuit substrates 120 and 130 in which other circuit blocks are disposed are stacked. Also in this case, the size of the photoelectric conversion device 100 can be reduced without sacrificing the area of the pixel array unit 10.

Note that the circuit elements constituting one functional block are not necessarily arranged on the same substrate, and may be arranged on different substrates.

As described above, according to the present embodiment, in the photoelectric conversion device having the function of correcting the noise component using the signal of the light-shielded pixel, it is possible to realize power saving and high precision correction.

### Second Embodiment

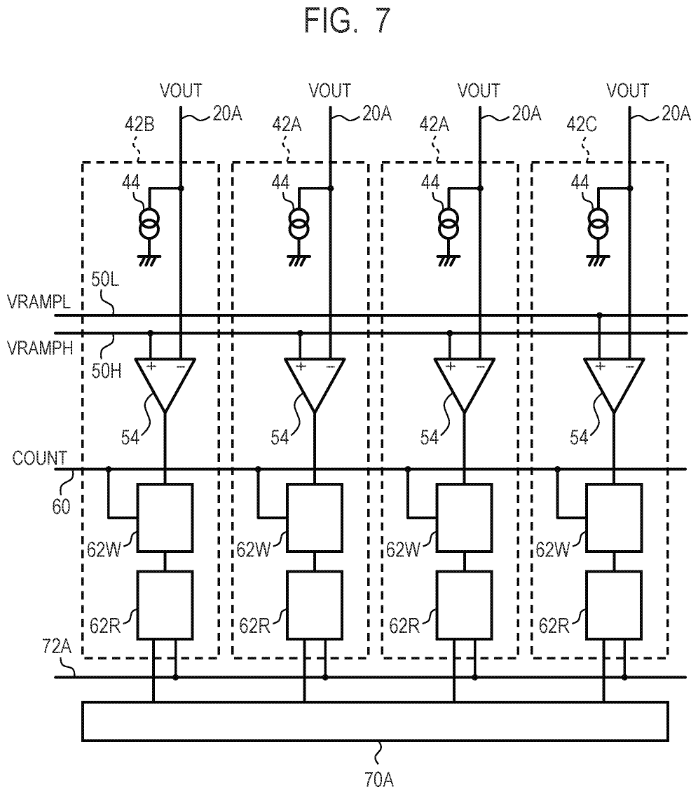

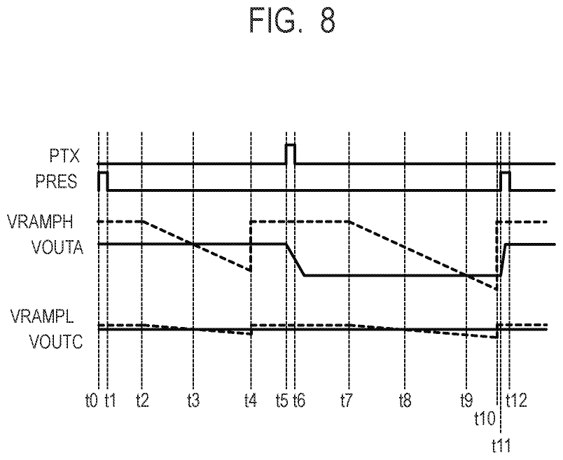

A photoelectric conversion device and a method of driving the same according to a second embodiment of the present invention will be described with reference to FIG. 7 and FIG. 8. Components similar to those of the photoelectric conversion device according to the first embodiment are denoted by the same reference numerals, and description thereof will be omitted or simplified. FIG. 7 is a circuit diagram illustrating a configuration example of a column circuit in the photoelectric conversion device according to the present embodiment. FIG. 8 is a timing chart illustrating a method of driving the photoelectric conversion device according to the present embodiment.

The photoelectric conversion device according to the present embodiment is the same as the photoelectric conversion device according to the first embodiment except that the configuration of the column circuits 42A, 42B, and 42C is different. In the present embodiment, differences from the photoelectric conversion device according to the first embodiment will be mainly described, and description of the same portions as those of the photoelectric conversion device according to the first embodiment will be appropriately omitted.

In the photoelectric conversion device according to the present embodiment, the reference signal input to the comparison circuits 54 of the column circuits 42A and 42B are different from the reference signal input to the comparison circuits 54 of the column circuits 42C. Specifically, the comparison circuits 54 of the column circuits 42A and 42B receive the reference signal VRAMPH from the reference signal generation circuit 48 via the reference signal line 50H, and the comparison circuits 54 of the column circuits 42C receive the reference signal VRAMPL from the reference signal generation circuit 48 via the reference signal line 50L. The reference signal VRAMPH and the reference signal VRAMPL have different ratios of change in signal level with respect to time. Specifically, in the reference signal VRAMPH, the rate of change in the signal level with respect to time is larger than that of the reference signal VRAMPL. In other words, the amplitude of the reference signal VRAMPH is larger than the amplitude of the reference signal VRAMPL. For example, when the reference signals VRAMPH and VRAMPL are ramp signals, the slope of the reference signal VRAMPH is larger than the slope of the reference signal VRAMPL. By configuring the photoelectric conversion device in this manner, AD conversion of the output signal of the pixel 16 may be performed with high accuracy, and horizontal stripe noise correction using the output signal of the pixel 16 may be performed with higher accuracy.

Next, the operation of the photoelectric conversion device according to the present embodiment will be described more specifically with reference to FIG. 8. The timing chart of FIG. 8 illustrates waveforms of the control signals PTX and PRES, the reference signals VRAMPH and VRAML, the voltage (voltage VOUTA) of the vertical output line 20A connected to the pixel 12, and the voltage (voltage VOUTC) of the vertical output line 20A connected to the pixel 16.

First, the AD conversion operation of a signal (voltage VOUTA) output from the pixel 12 to the vertical output line 20A will be described. Note that the AD conversion operation of the signal (voltage VOUTB) output from the pixel 14 to the vertical output line 20A is the same as the AD conversion operation of the signal (voltage VOUTA) output from the pixel 12 to the vertical output line 20A.

It is assumed that the control signal PSEL (not illustrated) of the row to be read out is at high-level immediately before time to. As a result, the select transistor M4 of the pixel 12 belonging to the row is turned on, and each of the pixels 12 can output a pixel signal to the vertical output line 20A of the corresponding column. It is also assumed that, immediately before the time to, the control signals PTX and PRES of the row to be read out are at low-level, and the reference signal VRAMPH is a predetermined reference voltage.

In a period from the time to t0 time t1, the vertical scanning circuit 30 controls the control signal PRES of the row to be read out to high-level. Accordingly, the reset transistor M2 of the pixel 12 belonging to the row is turned on, and the node FD is reset to a voltage corresponding to the voltage VDD. A voltage VOUTA corresponding to the reset voltage of the node FD (a pixel signal at the reset level of the pixel 12) is output to the vertical output line 20A connected to the pixel 12.

At subsequent time t2, the reference signal generation circuit 48A starts a slope operation in which the voltage of the reference signal VRAMPH changes with time. The counter circuit 58A starts counting up simultaneously with the start of the slope operation, and outputs a count signal COUNT indicating the count value to the column circuit 42A of each column via the count signal line 60.

The comparison circuit 54 of the column circuit 42A performs a comparison operation between the level of the voltage VOUTA and the level of the reference signal VRAMPH. The level of the output signal of the comparison circuit 54 is inverted at a timing when the magnitude relationship between the level of the voltage VOUTA and the level of the reference signal VRAMPH is changed, for example, at time t3 in FIG. 8.

The memory 62W of the column circuit 42A holds the count value indicated by the count signal COUNT output from the counter circuit 58A at the timing when the level of the output signal of the comparison circuit 54 is inverted, as digital data of the pixel signal of the reset level of the pixel 12. In this manner, the AD conversion of the pixel signal of the reset level of the pixel 12 is performed. After the digital data held in the memory 62W is transferred to the memory 62R, the digital data is transferred to the output circuit 80A in response to a control signal from the horizontal scanning circuit 70A.

At subsequent time t4, the reference signal generation circuit 48A resets the reference signal VRAMPH to the level of the reference voltage.

During a period from subsequent time t5 to time t6, the vertical scanning circuit 30 controls the control signal PTX of the row to be read out to high-level. Thereby, the transfer transistor M1 of the pixel 12 belonging to the row is turned on, and the charge accumulated in the photoelectric conversion element PD during the predetermined exposure period is transferred to the node FD. Thereby, the voltage of the node FD decreases according to an amount of charge transferred from the photoelectric conversion element PD, and the voltage VOUTA of the vertical output line 20A also decreases. A voltage VOUTA corresponding to the voltage of the node FD (pixel signal of the light signal level of the pixel 12) is output to the vertical output line 20A.

At subsequent time t7, the reference signal generation circuit 48A starts a slope operation in which the voltage of the reference signal VRAMPH changes with time. The counter circuit 58A starts counting up simultaneously with the start of the slope operation, and outputs a count signal COUNT indicating the count value to the column circuit 42A of each column via the count signal line 60.

The comparison circuit 54 of the column circuit 42A performs a comparison operation between the level of the voltage VOUTA and the level of the reference signal VRAMPH. The level of the output signal of the comparison circuit 54 is inverted at a timing when the magnitude relationship between the level of the voltage VOUTA and the level of the reference signal VRAMPH is changed, for example, at time t9 in FIG. 8.

The memory 62W of the column circuit 42A holds the count value indicated by the count signal COUNT output from the counter circuit 58A at the timing when the level of the output signal of the comparison circuit 54 is inverted, as digital data of the pixel signal of the light signal level of the pixel 12. In this manner, the AD conversion of the pixel signal of the light signal level of the pixel 12 is performed. After the digital data held in the memory 62W is transferred to the memory 62R, the digital data is transferred to the output circuit 80A in response to a control signal from the horizontal scanning circuit 70A.

The digital data of the pixel signal acquired in this manner is subjected to correction processing by digital CDS (correlated double sampling) in the output circuit 80A of the subsequent stage. In the correction processing by the digital CDS, the digital data of the pixel signal of the reset level is subtracted from the digital data of the pixel signal of the light signal level, and the noise component superimposed on the pixel signal of the light signal level is removed.

Next, the difference between the AD conversion operation of the signal (voltage VOUTC) output from the pixel 16 to the vertical output line 20A and the AD conversion operation of the voltage VOUTA will be described.

Since the pixel 16 does not have the photoelectric conversion element PD, the signal level of the vertical output line 20A hardly changes even after the control signal PTX becomes high-level from the time t5 to the time t6. Therefore, the slope of the reference signal VRAMPL used for AD conversion of the signal of the vertical output line 20A may be made smaller than the slope of the reference signal VRAMPH as illustrated in FIG. 8. This makes it possible to reduce the voltage value per 1 LSB and perform AD conversion with higher accuracy. Therefore, by performing the horizontal stripe noise correction using the output signal of the pixel 16 using the configuration of the present embodiment, the horizontal stripe noise correction may be performed with higher accuracy.

As described above, according to the present embodiment, in the photoelectric conversion device having the function of correcting the noise component using the signal of the light-shielded pixel, it is possible to improve the correction accuracy and acquire an image of good quality.

### Third Embodiment

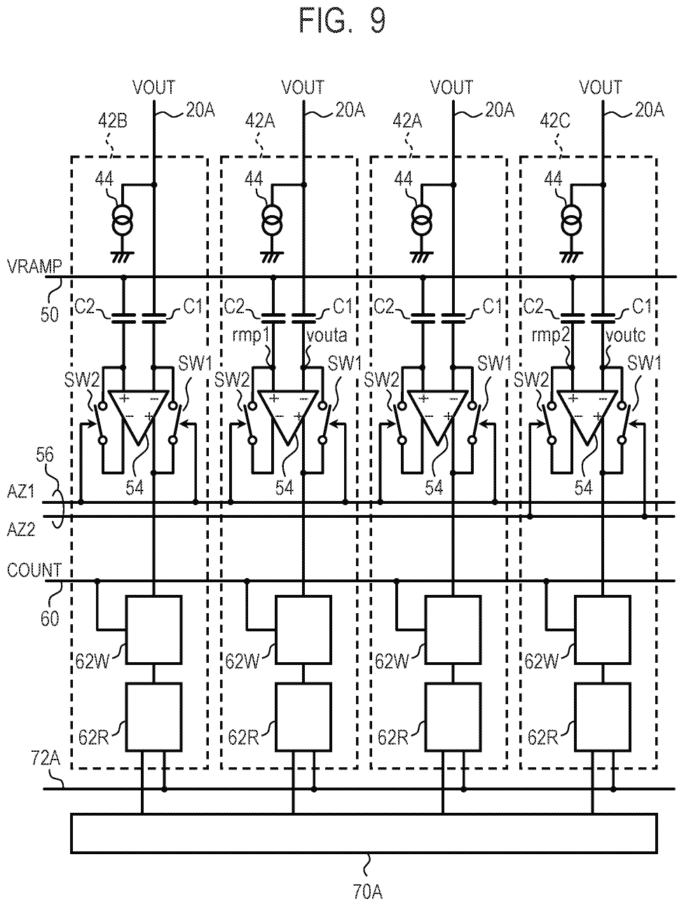

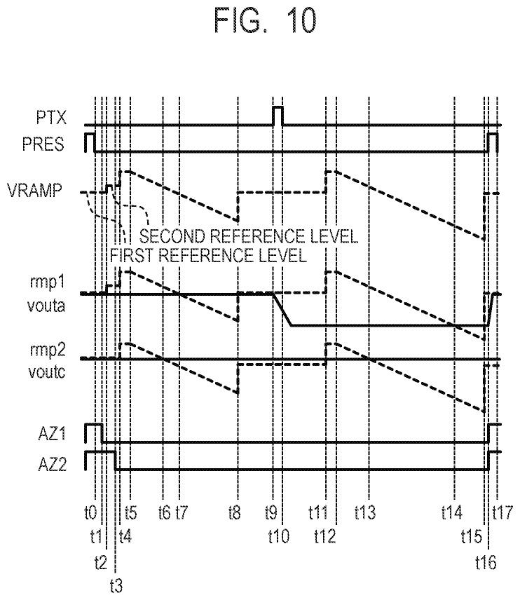

A photoelectric conversion device and a method of driving the same according to a third embodiment of the present invention will be described with reference to FIG. 9 and FIG. 10. Components similar to those of the photoelectric conversion device according to the first or second embodiment are denoted by the same reference numerals, and description thereof will be omitted or simplified. FIG. 9 is a circuit diagram illustrating a configuration example of a column circuit in the photoelectric conversion device according to the present embodiment. FIG. 10 is a timing chart illustrating a method of driving the photoelectric conversion device according to the present embodiment.

The photoelectric conversion device according to the present embodiment is the same as the photoelectric conversion device according to the first or second embodiment except that the configuration of the column circuits 42A, 42B, and 42C is different. In the present embodiment, differences from the photoelectric conversion device according to the first embodiment will be mainly described, and description of the same portions as those of the photoelectric conversion device according to the first embodiment will be appropriately omitted.

As illustrated in FIG. 9, each of the column circuits 42A, 42B, and 42C of the photoelectric conversion device according to the present embodiment further includes capacitors C1 and C2 and switches SW1 and SW2 in addition to the current source 44, the comparison circuit 54, and the memories 62W and 62R. The comparison circuit 54 includes, for example, a differential amplifier circuit, and includes a non-inverting input node (+), an inverting input node (−), a non-inverting output node (+), and an inverting output node (−).

The vertical output line 20A of each column is connected to the current source 44 of the corresponding column circuit 42 and one electrode of the capacitor C1. An inverting input node of the comparison circuit 54 is connected to the other electrode of the capacitor C1. A signal VOUT is input from the vertical output line 20A to the inverting input node of the comparison circuit 54 via the capacitor C1. The reference signal line 50 is connected to one electrode of the capacitor C2. A non-inverting input node of the comparison circuit 54 is connected to the other electrode of the capacitor C2. The non-inverting input node of the comparison circuit 54 receives the reference signal VRAMP from the reference signal line 50 via the capacitor C2. The switch SW1 is connected between the inverting input node and the non-inverting output node of the comparison circuit 54. The switch SW2 is connected between the non-inverting input node and the inverting output node of the comparison circuit 54. The non-inverting output node of the comparison circuit 54 is connected to the memory 62W.

The switches SW1 and SW2 of the column circuits 42A and 42B are controlled by a control signal AZ1 supplied from the control circuit 90 via a clamp control line 56. The switches SW1 and SW2 of the column circuit 42C are controlled by a control signal AZ2 supplied from the control circuit 90 via a clamp control line 56. The switches SW1 and SW2 are switches for controlling a reset operation of resetting a threshold voltage of the comparison circuit 54.

The comparison circuit 54 compares the level of the signal VOUT supplied from the vertical output line 20A via the capacitor C1 with the level of the reference signal VRAMP supplied from the reference signal line 50 via the capacitor C2, and outputs a signal according to the comparison result. For example, the comparison circuit 54 outputs a high-level signal when the level of the reference signal VRAMP is lower than the level of the signal VOUT. The comparison circuit 54 outputs a low-level signal when the level of the reference signal VRAMP is higher than the level of the signal VOUT. The relationship between the magnitude of the input signal and the level of the output signal may be reversed.

Note that the comparison circuit 54 is not limited to the illustrated configuration as long as it has a node to which a pixel signal is input and a node to which a reference signal is input and may perform an offset clamping operation of setting an offset based on voltages of the pixel signal and the reference signal.

As described above, in the photoelectric conversion device according to the present embodiment, the common control signal AZ1 is input to the comparison circuit 54 of the column circuits 42A and 42B, and the individual control signal AZ2 is input to the comparison circuit 54 of the column circuit 42C. By configuring the photoelectric conversion device in this manner, it is possible to suppress the degradation of the AD conversion accuracy in the column circuit 42C by affecting the inversion operation of the comparison circuit 54 of the column circuit 42C by power supply variation caused by the inversion operation of the comparison circuits 54 of the column circuits 42A and 42B. Thereby, AD conversion of the output signal of the pixel 16 may be performed with high accuracy, and horizontal stripe noise correction using the output signal of the pixel 16 may be performed with higher accuracy.

Next, the operation of the photoelectric conversion device according to the present embodiment will be described more specifically with reference to FIG. 10. The timing chart of FIG. 10 illustrates waveforms of the control signals PTX and PRES, the reference signal VRAMP, the signals rmp1, rmp2, vouta and voutc, and the control signals AZ1 and AZ2. Here, the signal rmp1 indicates the voltage of the non-inverting input node of the comparison circuit 54 of the column circuit 42A, and the signal rmp2 indicates the voltage of the non-inverting input node of the comparison circuit 54 of the column circuit 42C. The signal vouta indicates the voltage of the inverting input node of the comparison circuit 54 of the column circuit 42A, and the signal voutc indicates the voltage of the inverting input node of the comparison circuit 54 of the column circuit 42C.

First, the AD conversion operation of a signal (voltage VOUTA) output from the pixel 12 to the vertical output line 20A will be described. Note that the AD conversion operation of the signal (voltage VOUTB) output from the pixel 14 to the vertical output line 20A is the same as the AD conversion operation of the signal (voltage VOUTA) output from the pixel 12 to the vertical output line 20A.

It is assumed that the control signal PSEL (not illustrated) of the row to be read out is at high-level immediately before time t0. As a result, the select transistor M4 of the pixel 12 belonging to the row is turned on, and each of the pixels 12 can output a pixel signal to the vertical output line 20A of the corresponding column. It is also assumed that, immediately before time to, the control signal PTX of the row to be read out is at low-level, the control signals PRES, AZ1, and AZ2 of the row to be read out are at high-level, and the reference signal VRAMP is at a predetermined first reference level.

In a period until the time to, the control signal PRES of the row to be read out is at high-level. Accordingly, the reset transistor M2 of the pixel 12 belonging to the row is turned on, and the node FD is reset to a voltage corresponding to the voltage VDD.

At the time t0, the vertical scanning circuit 30 controls the control signal PRES of the row to be read out from high-level to low-level. Accordingly, the reset transistor M2 of the pixel 12 belonging to the row is turned off, and the reset state of the node FD is released. A voltage VOUTA corresponding to the reset voltage of the node FD (a pixel signal at the reset level of the pixel 12) is output to the vertical output line 20A connected to the pixel 12.

During a period until the time t0, the control signal AZ1 is at high-level. As a result, the switches SW1 and SW2 of the column circuit 42A are turned on, and the inverting input node and the non-inverting input node of the comparison circuit 54 are reset to the voltage of the reset level. That is, at the time to, one electrode of the capacitor C1 is at the voltage of the reset level of the pixel 12, and the other electrode of the capacitor C1 is at the voltage of the reset level of the comparison circuit 54. One electrode of the capacitor C2 is at the voltage of the first reference level of the reference signal VRAMP, and the other electrode of the capacitor C2 is at the voltage of the reset level of the comparison circuit 54. The threshold voltage of the comparison circuit 54 is reset to a voltage corresponding to a potential difference between the voltage of the reset level of the pixel 12 and the voltage of the first reference level of the reference signal VRAMP.

The threshold voltage of the comparison circuit 54 is a voltage corresponding to a difference between the signal level of the pixel signal and the signal level of the reference signal when the level of the comparison signal output from the comparison circuit 54 changes. That is, the comparison circuit 54 outputs comparison signals indicating different levels when the difference between the signal level of the pixel signal and the signal level of the reference signal is smaller than the threshold voltage and larger than the threshold voltage.

At subsequent time t1, the control circuit 90 controls the control signal AZ1 to low-level. As a result, the switches SW1 and SW2 of the column circuit 42A are turned off, the reset level of the pixel 12 is clamped by the capacitor C1, and the first reference level of the reference signal VRAMP is clamped by the capacitor C2.

At subsequent time t2, the reference signal generation circuit 48A changes the reference signal VRAMP from the first reference level to a second reference level higher than the first reference level. Thereby, the level of the signal rmp1 also increases according to the voltage difference between the first reference level and the second reference level.

At subsequent time t4, the reference signal generation circuit 48A increases the reference signal VRAMP from the second reference voltage to a predetermined start voltage. Then, the reference signal generation circuit 48A starts a slope operation of changing the voltage of the reference signal VRAMP with time from subsequent time t5. The counter circuit 58A starts counting up simultaneously with the start of the slope operation, and outputs a count signal COUNT indicating the count value to the column circuit 42A via the count signal line 60.

The comparison circuit 54 of the column circuit 42A compares the level of the voltage VOUTA (signal vouta) input via the capacitor C1 with the level of the reference signal VRAMP (signal ramp1) input via the capacitor C2. The level of the output signal of the comparison circuit 54 is inverted at a timing when the magnitude relationship between the level of the signal rmp1 and the level of the signal vouta is changed, for example, at time t7 in FIG. 10.

The memory 62W of the column circuit 42A holds the count value indicated by the count signal COUNT output from the counter circuit 58A at the timing when the level of the output signal of the comparison circuit 54 is inverted, as digital data of the pixel signal of the reset level of the pixel 12. In this manner, the AD conversion of the pixel signal of the reset level of the pixel 12 is performed. After the digital data held in the memory 62W is transferred to the memory 62R, the digital data is transferred to the output circuit 80A in response to a control signal from the horizontal scanning circuit 70A.

At subsequent time t8, the reference signal generation circuit 48A resets the reference signal VRAMP to the first reference level.

During a period from subsequent time t9 to time t10, the vertical scanning circuit 30 controls the control signal PTX of the row to be read out to high-level. Thereby, the transfer transistor M1 of the pixel 12 belonging to the row is turned on, and the charge accumulated in the photoelectric conversion element PD during the predetermined exposure period is transferred to the node FD. Thereby, the voltage of the node FD decreases according to an amount of charge transferred from the photoelectric conversion element PD, and the voltage VOUTA of the vertical output line 20A also decreases. A voltage VOUTA corresponding to the voltage of the node FD (pixel signal of the light signal level of the pixel 12) is output to the vertical output line 20A.

At subsequent time t11, the reference signal generation circuit 48A increases the reference signal VRAMP from the first reference voltage to a predetermined start voltage. Then, at subsequent time t12, the reference signal generation circuit 48A starts a slope operation in which the voltage of the reference signal VRAMP changes with time. The counter circuit 58A starts counting up simultaneously with the start of the slope operation, and outputs a count signal COUNT indicating the count value to the column circuit 42A of each column via the count signal line 60.

The comparison circuit 54 of the column circuit 42A compares the level of the voltage VOUTA (signal vouta) input via the capacitor C1 with the level of the reference signal VRAMP (signal rmp1) input via the capacitor C2. The level of the output signal of the comparison circuit 54 is inverted at a timing when the magnitude relationship between the level of the signal rmp1 and the level of the signal vouta is changed, for example, at a time t14 in FIG. 10.

The memory 62W of the column circuit 42A holds the count value indicated by the count signal COUNT output from the counter circuit 58A at the timing when the level of the output signal of the comparison circuit 54 is inverted, as digital data of the pixel signal of the light signal level of the pixel 12. In this manner, the AD conversion of the pixel signal of the light signal level of the pixel 12 is performed. After the digital data held in the memory 62W is transferred to the memory 62R, the digital data is transferred to the output circuit 80A in response to a control signal from the horizontal scanning circuit 70A.

The digital data of the pixel signal acquired in this manner is subjected to correction processing by digital CDS in the output circuit 80A of the subsequent stage. In the correction processing by the digital CDS, the digital data of the pixel signal of the reset level is subtracted from the digital data of the pixel signal of the light signal level, and the noise component superimposed on the pixel signal of the light signal level is removed.

Next, the difference between the AD conversion operation of the signal (voltage VOUTC) output from the pixel 16 to the vertical output line 20A and the AD conversion operation of the voltage VOUTA will be described.

In the column circuit 42C, the control signal AZ2 is controlled to low-level at time t3 after the time t2 at which the reference signal VRAMP is set to the second reference level. That is, in the column circuit 42C, at the time t3 when the switches SW1 and SW2 are turned off, the reset level of the pixel 16 is clamped by the capacitor C1, and the second reference level of the reference signal VRAMP is clamped by the capacitor C2. By this operation, during AD conversion of the pixel signal of the reset level of the pixel 16, the magnitude relationship between the level of the signal rmp2 and the level of the signal voutc is inverted at time t6 earlier than the time t7. At the time of AD conversion of the pixel signal of the light signal level of the pixel 16, the magnitude relationship between the level of the signal rmp2 and the level of the signal voutc is inverted at time t13 earlier than the time t14.

Thus, in the present embodiment, the clamp control signal (control signal AZ1) supplied to the comparison circuit 54 of the column circuits 42A and 42B and the clamp control signal (control signal AZ2) supplied to the comparison circuit 54 of the column circuit 42C are different control signals. By appropriately controlling the control signals AZ1 and AZ2, the output signal of the comparison circuit 54 of the column circuit 42C is inverted at a timing earlier than the output signal of the comparison circuit 54 of the column circuit 42A. Therefore, according to the present embodiment, it is possible to reduce the influence of power supply fluctuation or the like caused by the inversion operation of the comparison circuit 54 of the column circuits 42A and 42B on the inversion operation of the comparison circuit 54 of the column circuit 42C, and to suppress deterioration of the AD conversion accuracy in the column circuit 42C. As a result, AD conversion of the output signal of the pixel 16 may be performed with higher accuracy, and the horizontal stripe noise may be corrected with higher accuracy.

As described above, according to the present embodiment, in the photoelectric conversion device having the function of correcting the noise component using the signal of the light-shielded pixel, it is possible to improve the correction accuracy and acquire an image of good quality.

### Fourth Embodiment

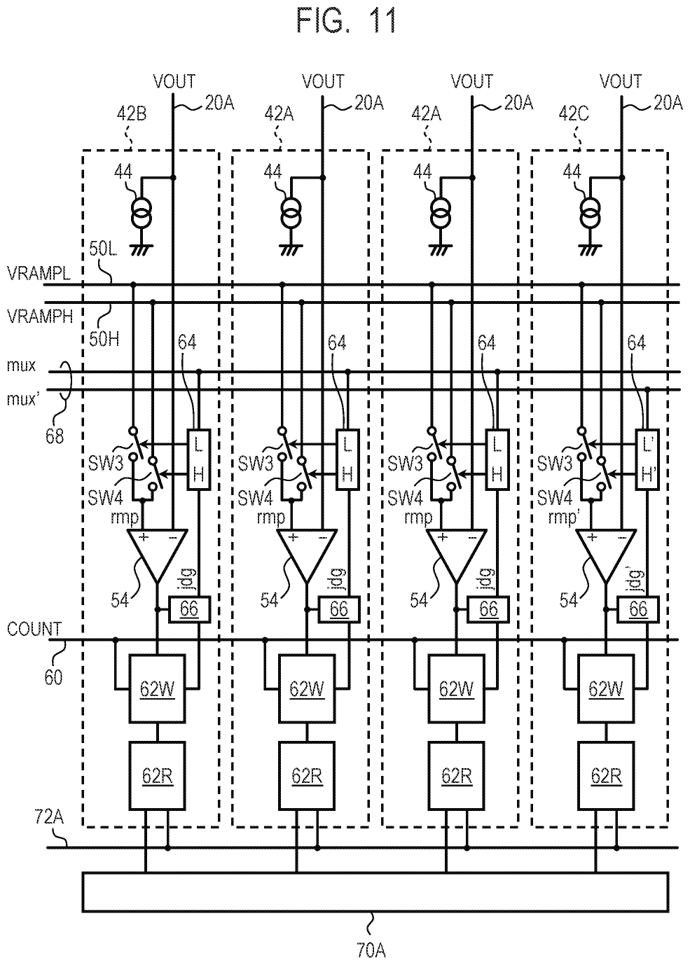

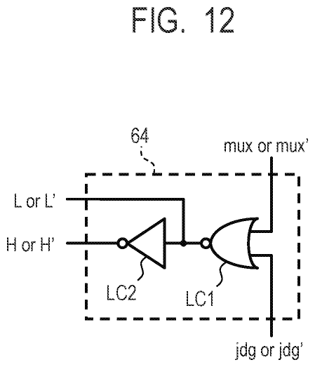

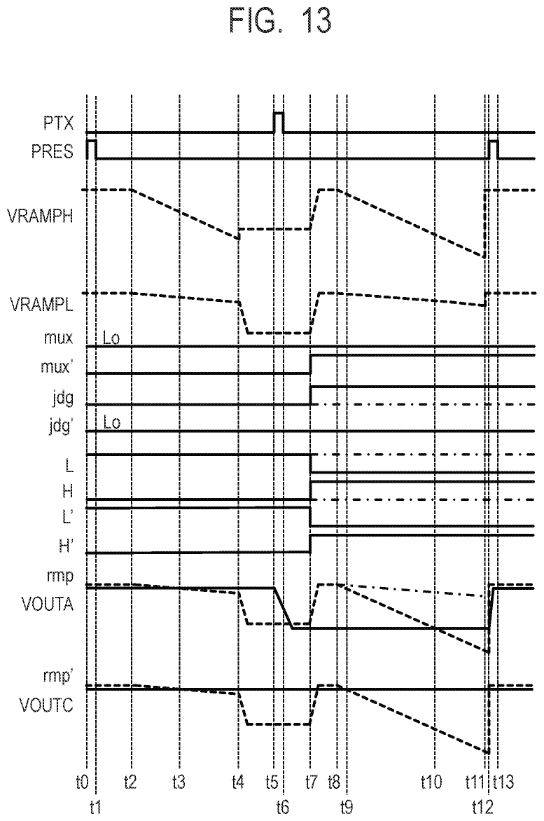

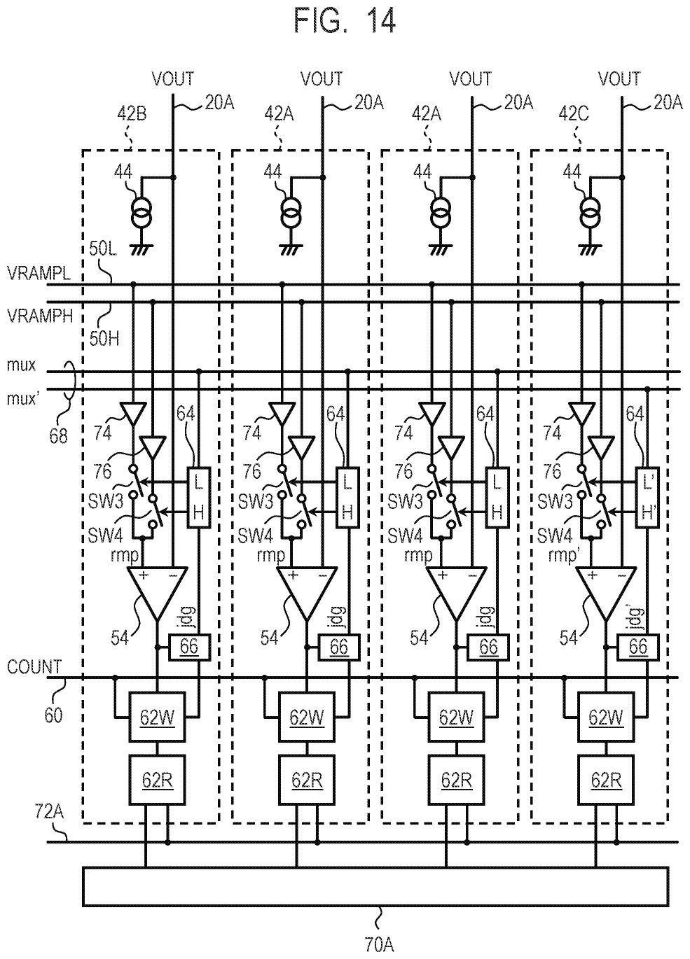

A photoelectric conversion device and a method of driving the same according to a fourth embodiment of the present invention will be described with reference to FIG. 11 to FIG. 14. Components similar to those of the photoelectric conversion devices according to the first to third embodiments are denoted by the same reference numerals, and description thereof will be omitted or simplified. FIG. 11 is a circuit diagram illustrating a configuration example of a column circuit in the photoelectric conversion device according to the present embodiment. FIG. 12 is a circuit diagram illustrating a configuration example of a switching unit in the photoelectric conversion device according to the present embodiment. FIG. 13 is a timing chart illustrating a method of driving the photoelectric conversion device according to the present embodiment. FIG. 14 is a circuit diagram illustrating a configuration example of a column circuit in a photoelectric conversion device according to a modification of the present embodiment.

The photoelectric conversion device according to the present embodiment is the same as the photoelectric conversion devices according to the first to third embodiments except that the configuration of the column circuits 42A, 42B, and 42C is different. In the present embodiment, differences from the photoelectric conversion device according to the second embodiment will be mainly described, and description of the same portions as those of the photoelectric conversion device according to the second embodiment will be appropriately omitted.

As illustrated in FIG. 11, each of the column circuits 42A, 42B, and 42C of the photoelectric conversion device according to the present embodiment further includes switches SW3 and SW4, a switching unit 64, and a determination result holding unit 66 in addition to the current source 44, the comparison circuit 54, and the memories 62W and 62R.

The reference signal line 50L from which the reference signal VRAMPL is output from the reference signal generation circuit 48A is connected to the non-inverting input node of the comparison circuit 54 via the switch SW3. The reference signal line 50H from which the reference signal VRAMPH is output from the reference signal generation circuit 48A is connected to the non-inverting input node of the comparison circuit 54 via the switch SW4. The switching unit 64 is connected to the control line 68. The determination result holding unit 66 is connected to the output node of the comparison circuit 54, the switching unit 64, and the memory 62W.

The switching unit 64 is controlled by a control signal mux or a control signal mux′ output from the control circuit 90 via the control line 68. The switches SW3 of the column circuits 42A and 42B are controlled by a control signal L output from the switching unit 64. The switches SW4 of the column circuits 42A and 42B are controlled by a control signal H output from the switching unit 64. The switch SW3 of the column circuit 42C is controlled by a control signal L′ output from the switching unit 64. The switch SW4 of the column circuit 42C is controlled by a control signal H′ output from the switching unit 64.

As illustrated in, e.g., FIG. 12, the switching unit 64 may be configured by a two-input NOR circuit LC1 and a NOT circuit LC2. An output node of the NOR circuit LC1 is connected to an input node of the NOT circuit LC2. A control signal mux from the control circuit 90 and a determination signal jdg from the determination result holding unit 66 are input to the NOR circuit LC1 of the switching unit 64 of the column circuits 42A and 42B. An output signal of the NOR circuit LC1 is input to the NOT circuit LC2. An output signal of the NOR circuit LC1 becomes the control signal L, and an output signal of the NOT circuit LC2 becomes the control signal H. That is, the switching unit 64 of the column circuits 42A and 42B outputs the control signals L and H corresponding to the control signal mux and the determination signal jdg. A control signal mux′ from the control circuit 90 and a determination signal jdg′ from the determination result holding unit 66 are input to the NOR circuit LC1 of the switching unit 64 of the column circuit 42C. An output signal of the NOR circuit LC1 is input to the NOT circuit LC2. An output signal of the NOR circuit LC1 becomes the control signal L′, and an output signal of the NOT circuit LC2 becomes the control signal H′. That is, the switching unit 64 of the column circuit 42C outputs the control signals L′ and H′ corresponding to the control signal mux′ and the determination signal jdg′.

Next, the operation of the photoelectric conversion device according to the present embodiment will be described more specifically with reference to FIG. 13. The timing chart of FIG. 13 illustrates waveforms of control signals PTX and PRES, reference signals VRAMPH and VRAMPL, control signals mux, mux′, L, H, L′ and H′, determination signals jdg and jdg′, signals rmp and rmp′, and voltages VOUTA and VOUTC. Here, the signal rmp represents a signal input to the non-inverting input node of the comparison circuit 54 of the column circuit 42A, and the signal rmp′ represents a signal input to the non-inverting input node of the comparison circuit 54 of the column circuit 42C. The voltage VOUTA indicates the voltage of the vertical output line 20A connected to the pixel 12, and the voltage VOUTC indicates the voltage of the vertical output line 20A connected to the pixel 16.

First, the AD conversion operation of a signal (voltage VOUTA) output from the pixel 12 to the vertical output line 20A will be described. Note that the AD conversion operation of the signal (voltage VOUTB) output from the pixel 14 to the vertical output line 20A is the same as the AD conversion operation of the signal (voltage VOUTA) output from the pixel 12 to the vertical output line 20A.

It is assumed that the control signal PSEL (not illustrated) of the row to be read out is at high-level immediately before time to. As a result, the select transistor M4 of the pixel 12 belonging to the row is turned on, and each of the pixels 12 can output a pixel signal to the vertical output line 20A of the corresponding column. It is also assumed that, immediately before the time to, the control signals PTX and PRES of the row to be read out are at low-level, and the reference signals VRAMPH and VRAMPL are predetermined reference voltages.

It is assumed that the control signal mux and the determination signal jdg are at low-level immediately before the time to. That is, the switching unit 64 of the column circuit 42A outputs a high-level control signal L and a low-level control signal H in response to the input of the low-level control signal mux and the low-level determination signal jdg. The switch SW3 of the column circuit 42A is turned on in response to the high-level control signal L, and the switch SW4 of the column circuit 42A is turned off in response to the low-level control signal H.

During a period from the time to t0 time t1, the vertical scanning circuit 30 controls the control signal PRES of the row to be read out to high-level. Accordingly, the reset transistor M2 of the pixel 12 belonging to the row is turned on, and the node FD is reset to a voltage corresponding to the voltage VDD. A voltage VOUTA corresponding to the reset voltage of the node FD (a pixel signal at the reset level of the pixel 12) is output to the vertical output line 20A connected to the pixel 12.

At subsequent time t2, the reference signal generation circuit 48A starts a slope operation in which the voltages of the reference signals VRAMPH and VRAMPL change with time. At this time, since the switch SW3 is on and the switch SW4 is off in the column circuit 42A, the non-inverting input node of the comparison circuit 54 of the column circuit 42A receives the reference signal VRAMPL among these reference signals. FIG. 13 illustrates this signal input to the non-inverting input node of the comparison circuit 54 of the column circuit 42A as a signal rmp. The counter circuit 58A starts counting up simultaneously with the start of the slope operation, and outputs a count signal COUNT indicating the count value to the column circuit 42A of each column via the count signal line 60.

The comparison circuit 54 of the column circuit 42A compares the level of the voltage VOUTA with the level of the signal rmp (reference signal VRAMPL). The level of the output signal of the comparison circuit 54 is inverted from, for example, high-level to low-level at a timing when the magnitude relationship between the level of the voltage VOUTA and the level of the signal rmp changes, for example, at time t3 in FIG. 13.

The memory 62W of the column circuit 42A holds the count value indicated by the count signal COUNT output from the counter circuit 58A at the timing when the level of the output signal of the comparison circuit 54 is inverted, as digital data of the pixel signal of the reset level of the pixel 12. In this manner, the AD conversion of the pixel signal of the reset level of the pixel 12 is performed. After the digital data held in the memory 62W is transferred to the memory 62R, the digital data is transferred to the output circuit 80A in response to a control signal from the horizontal scanning circuit 70A.

At subsequent time t4, the reference signal generation circuit 48A transitions the reference signals VRAMPH and VRAMPL to a predetermined level serving as a reference for luminance value determination. That is, when the signal level of the vertical output line 20A is lower than the signal level set in the reference signals VRAMPH and VRAMPL, it is determined that the object has low luminance.

During a period from subsequent time t5 to time t6, the vertical scanning circuit 30 controls the control signal PTX of the row to be read out to high-level. Thereby, the transfer transistor M1 of the pixel 12 belonging to the row is turned on, and the charge accumulated in the photoelectric conversion element PD during the predetermined exposure period is transferred to the node FD. Thereby, the voltage of the node FD decreases according to an amount of charge transferred from the photoelectric conversion element PD, and the voltage VOUTA of the vertical output line 20A also decreases. A voltage VOUTA corresponding to the voltage of the node FD (pixel signal of the light signal level of the pixel 12) is output to the vertical output line 20A.

When the signal level of the vertical output line 20A is lower than the level of the signal rmp (reference signal VRAMPL) by transferring the signal charge to the node FD, that is, when the object is not dark or low luminance, the level of the output signal of the comparison circuit 54 is inverted from low-level to high-level. The determination result holding unit 66 holds the output signal from the comparison circuit 54, and reflects the holding result in the determination signal jdg at subsequent time t7. That is, at the time t7, the level of the determination signal jdg transitions from low-level to high-level. The switching unit 64 of the column circuit 42A outputs the low-level control signal L and the high-level control signal H in response to the low-level control signal mux and the high-level determination signal jdg. The switch SW3 of the column circuit 42A receives a low-level control signal L and turns off, and the switch SW4 of the column circuit 42A receives a high-level control signal H and turns on. That is, the signal rmp supplied to the non-inverting input node of the comparison circuit 54 is switched from the reference signal VRAMPL to the reference signal VRAMPH.

When the relationship between the signal level of the vertical output line 20A and the level of the signal rmp (reference signal VRAMPL) does not change even when the signal charge is transferred to the node FD, that is, when the object is dark or low luminance, the level of the output signal of the comparison circuit 54 remains low. The determination result holding unit 66 holds the output signal from the comparison circuit 54, and reflects the holding result in the determination signal jdg at the subsequent time t7, but the determination signal jdg remains at low-level because the level of the output signal of the comparison circuit 54 is at low-level. Therefore, the switch SW3 of the column circuit 42A remains on, the switch SW4 of the column circuit 42A remains off, and the signal rmp supplied to the non-inverting input node of the comparison circuit 54 remains unchanged as the reference signal VRAMPL. In FIG. 13, the waveforms of the determination signal jdg, the control signals H and L, and the signal rmp in the case where the object is dark or low luminance are illustrated by one-dot-chain lines.

Similarly, at the time t7, the reference signal generation circuit 48A resets the reference signals VRAMPH and VRAMPL to a predetermined reference voltage.

At subsequent time t8, the reference signal generation circuit 48A starts a slope operation in which the voltages of the reference signals VRAMPH and VRAMPL change with time. At this time, since the switch SW3 is off and the switch SW4 is on in the column circuit 42A, the signal rmp input to the non-inverting input node of the comparison circuit 54 of the column circuit 42A becomes the reference signal VRAMPH among these reference signals. The counter circuit 58A starts counting up simultaneously with the start of the slope operation, and outputs a count signal COUNT indicating the count value to the column circuit 42A of each column via the count signal line 60.

The comparison circuit 54 of the column circuit 42A compares the level of the voltage VOUTA with the level of the signal rmp (reference signal VRAMPH). The level of the output signal of the comparison circuit 54 is inverted from, for example, high-level to low-level at a timing when the magnitude relationship between the level of the voltage VOUTA and the level of the signal rmp changes, for example, at time t10 in FIG. 13.

The memory 62W of the column circuit 42A holds the count value indicated by the count signal COUNT output from the counter circuit 58A at the timing when the level of the output signal of the comparison circuit 54 is inverted, as digital data of the pixel signal of the light signal level of the pixel 12. In this manner, the AD conversion of the pixel signal of the light signal level of the pixel 12 is performed. The memory 62W of the column circuit 42A also holds data (determination signal jdg) held by the determination result holding unit 66 as luminance determination data. The digital data and the luminance determination data held in the memory 62W are transferred to the memory 62R, and then transferred to the output circuit 80A in response to a control signal from the horizontal scanning circuit 70A.

The digital data of the pixel signal acquired in this manner is subjected to correction processing by digital CDS in the output circuit 80A of the subsequent stage. In the correction processing by the digital CDS, the digital data of the pixel signal of the reset level is subtracted from the digital data of the pixel signal of the light signal level, and the noise component superimposed on the pixel signal of the light signal level is removed.

At this time, since the slope of the reference signal VRAMPH used for the AD conversion of the light signal level is larger than that of the reference signal VRAMPL used for the AD conversion of the reset level, the AD conversion result becomes smaller by the ratio of the inclination. Therefore, in the digital CDS processing, a digital gain corresponding to the ratio of inclination is applied to the digital data of the light signal level, and then the digital data of the reset level is subtracted. When the object is dark or low luminance, the reference signal VRAMPL is also used for the AD conversion of the light signal level, so that digital CDS processing is directly performed without applying digital gain to digital data of the light signal level.

The digital gain processing on the digital data of the light signal level may be performed based on the luminance determination data transferred to the output circuit 80A together with the digital data of the pixel signal. That is, when the luminance determination data has a value corresponding to the high level of the determination signal jdg (for example, ‘1’), digital gain processing is performed on the digital data of the light signal level. When the luminance determination data has a value corresponding to the low level of the determination signal jdg (for example, ‘0’), the digital gain processing is not performed on the digital data of the light signal level.

As described above, the photoelectric conversion device according to the present embodiment is configured to be capable of switching the reference signal used for the AD conversion according to the luminance of the object. This makes it possible to perform high-precision AD conversion using a reference signal having a small inclination when the object has a low luminance, and to perform high-speed AD conversion using a reference signal having a large inclination when the object has a high luminance.

Next, the difference between the AD conversion operation of the signal (voltage VOUTC) output from the pixel 16 to the vertical output line 20A and the AD conversion operation of the voltage VOUTA will be described.

In the column circuit 42C, instead of the control signals mux, L, and H and the determination signal jdg, the control signals mux′, L′, and H′ and the determination signal jdg′ are used. It is assumed that the control signal mux′ and the determination signal jdg′ are at low-level immediately before time t0. The switching unit 64 of the column circuit 42C outputs a high-level control signal L′ and a low-level control signal H′ in response to the input of the low-level control signal mux′ and the low-level determination signal jdg′. The switch SW3 of the column circuit 42C is turned on in response to the high-level control signal L′, and the switch SW4 of the column circuit 42C is turned off in response to the low-level control signal H′.

The operation of the column circuit 42C until the time t7 is basically the same as the operation of the column circuit 42A except that the control signals mux′, L′, H′ and the determination signal jdg′ are used instead of the control signals mux, L, H and the determination signal jdg. However, since the pixel 16 is a light-shielded pixel that does not include the photoelectric conversion unit, the level of the voltage VOUTC does not change even when the transfer transistor is turned on during the period from the time t5 to the time t6, and the output signal of the comparison circuit 54 is maintained at low-level. Therefore, the switch SW3 of the column circuit 42C remains on and the switch SW4 of the column circuit 42C remains off, and the signal rmp′ supplied to the non-inverting input node of the comparison circuit 54 remains unchanged as the reference signal VRAMPL.

At subsequent time t7, the control circuit 90 controls the control signal mux′ from low-level to high-level. Thereby, the switching unit 64 of the column circuit 42C always outputs the low-level control signal L′ and the high-level control signal H′ regardless of the level of the determination signal jdg′. The switch SW3 of the column circuit 42C receives the low-level control signal L′ and turns off, and the switch SW4 of the column circuit 42C receives the high-level control signal H′ and turns on. That is, the AD conversion of the pixel signal of the light signal level in the column circuit 42C is always performed using the reference signal RAMPH. Thus, the column circuit 42C can acquire data for correcting the AD conversion result of the pixel signal of the pixel 12 when the object has high luminance.

As described above, when the object has high luminance, the reference signal VRAMPL is used for the AD conversion of the pixel signal of the reset level in the column circuit 42A, and the reference signal VRAMPH is used for the AD conversion of the pixel signal of the light signal level in the column circuit 42A. However, the time required for the inversion, i.e., the time from when the levels of the two input signals to the comparison circuit 54 become equal to when the level of the output signal is inverted, is different between the case where the reference signal VRAMPL is used and the case where the reference signal VRAMPH is used. Further, this time difference is not proportional to the ratio of the slope gradient of the reference signal VRAMPL to the slope gradient of the reference signal VRAMPH. Therefore, in the digital CDS process of subtracting the digital data of the reset level after applying the digital gain to the digital data of the light signal level, the noise component superimposed on the digital data of the light signal level cannot be completely removed. As a result, there is a possibility that correction residue may occur in the data after the digital CDS processing, resulting in deterioration of image quality.

Therefore, in the present embodiment, the AD conversion of the pixel signal of the light signal level in the column circuit 42C is always performed under the same conditions as those of the AD conversion conditions used in the case where the object has high luminance in the column circuit 42A. Similarly to the digital data acquired by the column circuit 42A, digital CDS processing is performed on the digital data acquired by the column circuit 42C, in which digital gain is applied to the digital data of the light signal level, and then the digital data of the reset level is subtracted. As a result, it is possible to acquire the noise component corresponding to the correction residue generated after the digital CDS processing of the digital data acquired by the column circuit 42A from the digital data acquired by the column circuit 42C. Therefore, by subtracting the data after the digital CDS processing of the data acquired from the column circuit 42C from the data after the digital CDS processing of the data acquired from the column circuit 42A, it is possible to acquire data in which the correction residue is reduced.

In the configuration example of FIG. 11, the control signal mux of the switching unit 64 of the column circuit 42A and the control signal mux′ of the switching unit 64 of the column circuit 42C are individually provided, whereby the AD conversion gain in the column circuit 42C and the AD conversion gain in the column circuit 42A are independently controlled. However, the method of controlling the AD conversion gain in the column circuit 42C independently of the AD conversion gain in the column circuit 42A is not limited thereto. For example, instead of providing the control line 68, the control line of the switching unit 64 of the column circuits 42A and 42B and the control line of the switching unit 64 of the column circuit 42C may be separately provided and independently controlled.

Further, as in the configuration example illustrated in, e.g., FIG. 14, buffer circuits 74 and 76 may be provided in each of the column circuits 42A, 42B, and 42C, and reference signals VRAMPL and VRAMPH may be input to the comparison circuit 54 via the buffer circuits 74 and 76. By configuring the column circuits 42A, 42B, and 42C in this manner, it is possible to suppress variation in load capacitance of the reference signal lines 50L and 50H according to the selection state of the reference signals in the column circuits 42A, 42B, and 42C, and to improve image quality.

As described above, according to the present embodiment, in the photoelectric conversion device having the function of correcting the noise component using the signal of the light-shielded pixel, it is possible to improve the correction accuracy and acquire an image of good quality.

### Fifth Embodiment

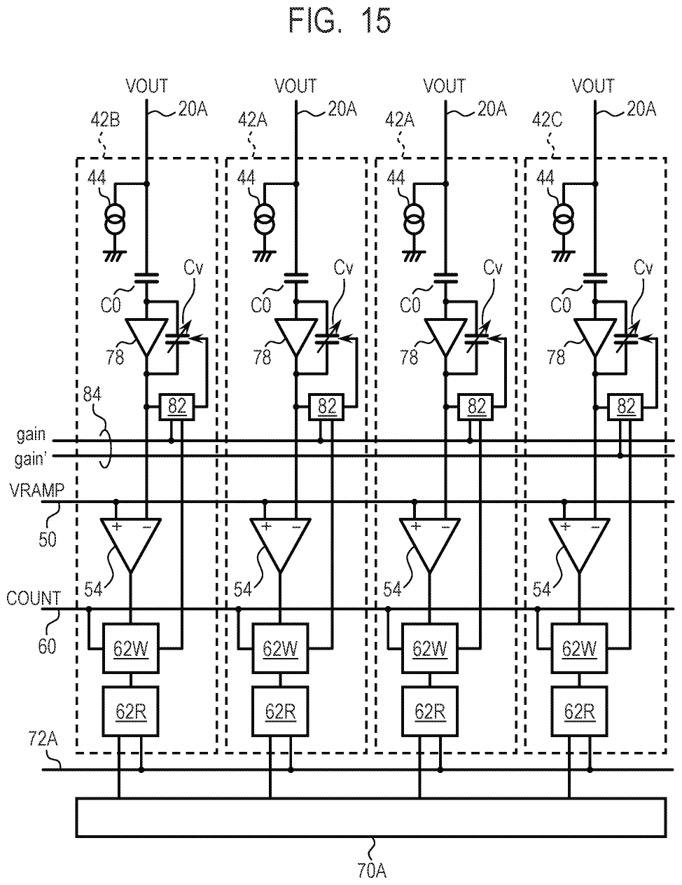

A photoelectric conversion device and a method of driving the same according to a fifth embodiment of the present invention will be described with reference to FIG. 15. Components similar to those of the photoelectric conversion devices according to the first to fourth embodiments are denoted by the same reference numerals, and description thereof will be omitted or simplified. FIG. 15 is a circuit diagram illustrating a configuration example of a column circuit in the photoelectric conversion device according to the present embodiment.

In the fourth embodiment, the AD conversion gain in the AD conversion of the pixel signal of the light signal level is selected according to the luminance of the object, the gain of the amplifier circuit may be selected according to the luminance of the object. In the present embodiment, a configuration example in which the gain of the amplifier circuit is selected according to the luminance of the object will be described.

The photoelectric conversion device according to the present embodiment is the same as the photoelectric conversion device according to the first embodiment except that the configuration of the column circuits 42A, 42B, and 42C is different. In the present embodiment, differences from the photoelectric conversion device according to the first embodiment will be mainly described, and description of the same portions as those of the photoelectric conversion device according to the first embodiment will be appropriately omitted.

As illustrated in FIG. 15, each of the column circuits 42A, 42B, and 42C of the photoelectric conversion device according to the present embodiment further includes an amplifier circuit including an amplifier 78, capacitors C0 and Cv, and a determination unit 82 in addition to the current source 44, the comparison circuit 54, and the memories 62W and 62R.

The vertical output line 20A of each column is connected to the current source 44 of the corresponding column circuit 42 and one electrode of the capacitor C0. The other electrode of the capacitor C0 is connected to an input node of the amplifier 78. An output node of the amplifier 78 is connected to the inverting input node of the comparison circuit 54 and the determination unit 82. The capacitor Cv is connected between the input node and the output node of the amplifier 78. The capacitor Cv is a variable capacitance circuit configured to be capable of changing a capacitance value according to a signal output from the determination unit 82. The capacitor Cv may take at least a first capacitance value and a second capacitance value larger than the first capacitance value in response to the signal from the determination unit 82. Since the gain of the amplifier circuit is represented by the ratio (C0/Cv) between the capacitance value of the capacitor C0 and the capacitance value of the capacitor Cv, the gain of the amplifier circuit may be switched by switching the capacitance value of the capacitor Cv. A control signal “gain” is input from the control circuit 90 to the determination unit 82 of the column circuits 42A and 42B via the control line 84. A control signal “gain′” is input from the control circuit 90 to the determination unit 82 of the column circuit 42C via the control line 84.

The determination unit 82 has a function of controlling the gain of the amplifier circuit according to the signal level of the vertical output line 20A. More specifically, the determination unit 82 determines whether or not an amount of change in the signal level of the vertical output line 20A when the charge held by the photoelectric conversion element PD is transferred to the node FD exceeds a predetermined value. Then, a signal for controlling the capacitance value of the capacitor Cv is output to the capacitor Cv in accordance with the determination result and the control signal “gain” or the control signal “gain”. By separating the control signal “gain” input to the determination unit 82 of the column circuits 42A and 42B and the control signal “gain′” input to the determination unit 82 of the column circuit 42C, the gain of the amplifier circuit of the column circuits 42A and 42B and the gain of the amplifier circuit of the column circuit 42C may be individually set.

The gains of the amplifier circuits in the column circuits 42A, 42B, and 42C may be set in the same manner as the AD conversion gain in the fourth embodiment. That is, the gains of the amplifier circuits of the column circuits 42A and 42B at the time of AD conversion of the pixel signals of the light signal level are appropriately set according to the luminance of the object. Specifically, when the amount of change in the signal level of the vertical output line 20A is less than a predetermined value, that is, when the object is dark or low luminance, the determination unit 82 of the column circuits 42A and 42B sets the capacitor Cv to the first capacitance value and sets the gain of the amplifier circuit to a first gain. When the amount of change in the signal level of the vertical output line 20A is equal to or greater than the predetermined value, that is, when the object has high luminance, the determination unit 82 of the column circuits 42A and 42B sets the capacitor Cv to the second capacitance value and sets the gain of the amplifier circuit to a second gain lower than the first gain. On the other hand, in the amplifier circuit of the column circuit 42C at the time of the AD conversion of the pixel signal of the light signal level, the capacitor Cv is set to the second capacitance value and the gain of the amplifier circuit is set to the second gain regardless of the luminance of the object.

By setting the gain of the amplifier circuit in this manner, similarly to the case of the fourth embodiment, the noise component corresponding to the correction residue generated after the digital CDS processing of the digital data acquired by the column circuit 42A may be acquired from the digital data acquired by the column circuit 42C. Therefore, by subtracting the data after the digital CDS processing of the data acquired from the column circuit 42C from the data after the digital CDS processing of the data acquired from the column circuit 42A, it is possible to acquire data in which the correction residue is reduced.

As described above, according to the present embodiment, in the photoelectric conversion device having the function of correcting the noise component using the signal of the light-shielded pixel, it is possible to improve the correction accuracy and acquire an image of good quality.

### Sixth Embodiment

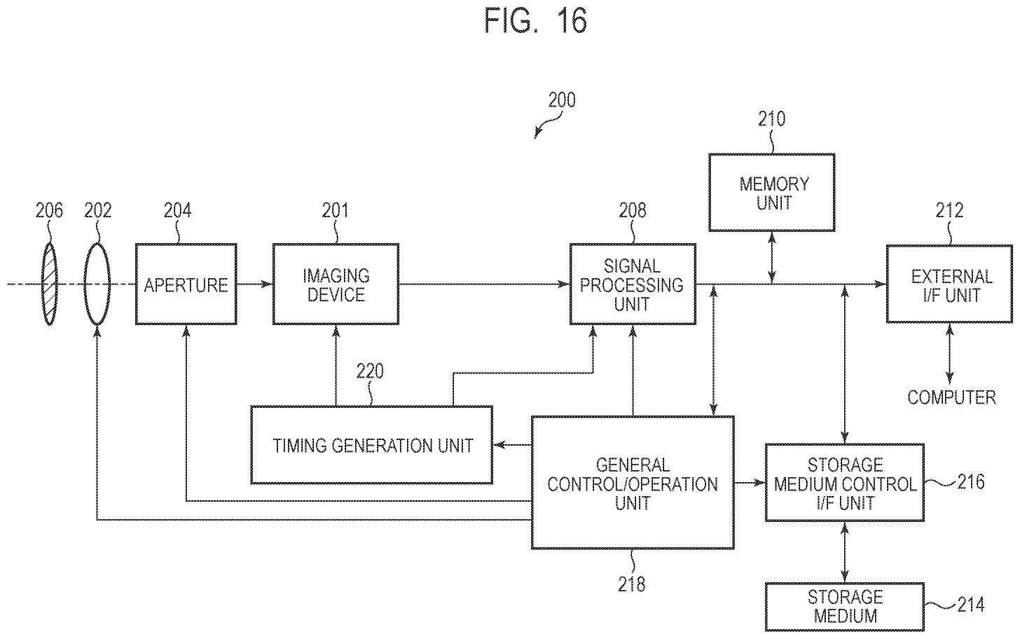

An imaging system according to a sixth embodiment of the present invention will be described with reference to FIG. 16. FIG. 16 is a block diagram illustrating a schematic configuration of the imaging system according to the present embodiment.

The photoelectric conversion device 100 described in the first to fifth embodiments may be applied to various imaging systems. Examples of applicable imaging systems include digital still cameras, digital camcorders, surveillance cameras, copying machines, facsimiles, mobile phones, on-vehicle cameras, observation satellites, and the like. A camera module including an optical system such as a lens and an imaging device is also included in the imaging system. FIG. 16 is a block diagram of a digital still camera as an example of these.

The imaging system 200 illustrated in FIG. 16 includes an imaging device 201, a lens 202 for forming an optical image of an object on the imaging device 201, an aperture 204 for varying an amount of light passing through the lens 202, and a barrier 206 for protecting the lens 202. The lens 202 and the aperture 204 form an optical system that collects light on the imaging device 201. The imaging device 201 is the photoelectric conversion device 100 described in any of the first to fifth embodiments, and converts an optical image formed by the lens 202 into image data.

The imaging system 200 also includes a signal processing unit 208 that processes an output signal output from the imaging device 201. The signal processing unit 208 generates image data from a digital signal output from the imaging device 201.

The signal processing unit 208 performs various corrections and compressions as necessary and outputs the processed image data. The imaging device 201 may include an AD conversion unit that generates a digital signal to be processed by the signal processing unit 208. The AD conversion unit may be formed in a semiconductor layer (semiconductor substrate) in which the photoelectric conversion unit of the imaging device 201 is formed, or may be formed in a semiconductor layer different from the semiconductor layer in which the photoelectric conversion unit of the imaging device 201 is formed. The signal processing unit 208 may be formed on the same semiconductor layer as the imaging device 201.

The imaging system 200 further includes a memory unit 210 for temporarily storing image data, and an external interface unit (external I/F unit) 212 for communicating with an external computer or the like. Further, the imaging system 200 includes a storage medium 214 such as a semiconductor memory for storing or reading out the imaging data, and a storage medium control interface unit (storage medium control I/F unit) 216 for storing or reading out the imaging data on or from the storage medium 214. The storage medium 214 may be built in the imaging system 200, or may be detachable.

The imaging system 200 further includes a general control/operation unit 218 that controls various calculations and operations of the entire digital still camera, and a timing generation unit 220 that outputs various timing signals to the imaging device 201 and the signal processing unit 208. Here, the timing signal or the like may be input from the outside, and the imaging system 200 may include at least the imaging device 201 and the signal processing unit 208 that processes an output signal output from the imaging device 201.

The imaging device 201 outputs the imaging signal to the signal processing unit 208. The signal processing unit 208 performs predetermined signal processing on the imaging signal output from the imaging device 201, and outputs image data. The signal processing unit 208 generates an image using the imaging signal.

As described above, according to the present embodiment, it is possible to realize an imaging system to which the photoelectric conversion device 100 according to the first to fifth embodiments is applied.

### Seventh Embodiment

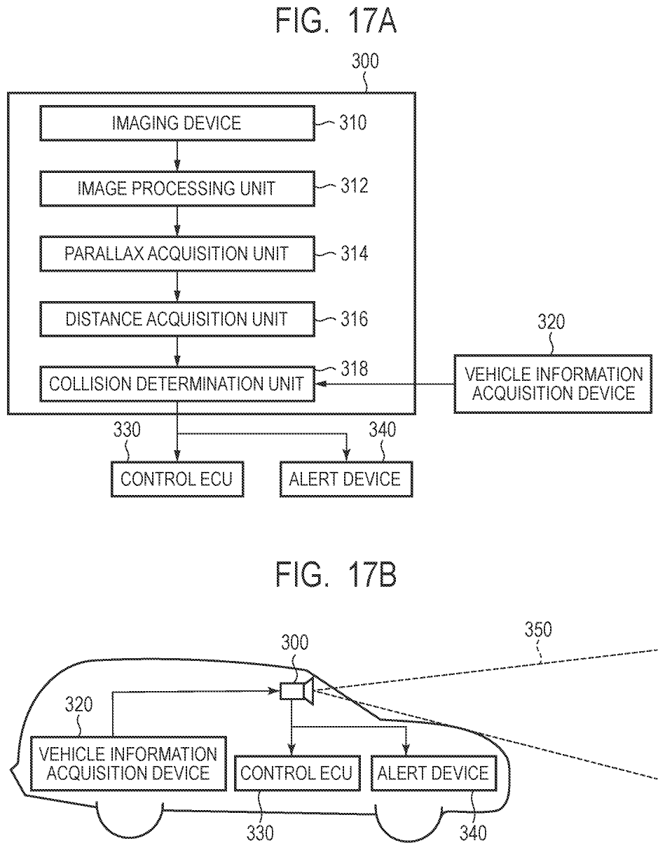

An imaging system and a movable object according to a seventh embodiment of the present invention will be described with reference to FIG. 17A and FIG. 17B. FIG. 17A is a diagram illustrating a configuration of the imaging system according to the present embodiment. FIG. 17B is a diagram illustrating a configuration of a movable object according to the present embodiment.

FIG. 17A illustrates an example of an imaging system relating to an on-vehicle camera. The imaging system 300 includes an imaging device 310. The imaging device 310 is the photoelectric conversion device 100 described in any one of the first to fifth embodiments. The imaging system 300 includes an image processing unit 312 that performs image processing on a plurality of image data acquired by the imaging device 310, and a parallax acquisition unit 314 that calculates parallax (phase difference of parallax images) from the plurality of image data acquired by the imaging device 310. The imaging system 300 includes a distance acquisition unit 316 that calculates a distance to an object based on the calculated parallax, and a collision determination unit 318 that determines whether or not there is a possibility of collision based on the calculated distance. Here, the parallax acquisition unit 314 and the distance acquisition unit 316 are examples of a distance information acquisition unit that acquires distance information to the object. That is, the distance information may be information on a parallax, a defocus amount, a distance to the object, and the like. The collision determination unit 318 may determine the collision possibility using any of these pieces of distance information. The distance information acquisition unit may be implemented by dedicated hardware or software modules. Further, it may be implemented by FPGA (Field Programmable Gate Array), ASIC (Application Specific Integrated circuit), or the like, or may be implemented by a combination of these.

The imaging system 300 is connected to a vehicle information acquisition device 320, and may acquire vehicle information such as a vehicle speed, a yaw rate, and a steering angle. Further, the imaging system 300 is connected to a control ECU 330 which is a control device that outputs a control signal for generating a braking force to the vehicle based on the determination result of the collision determination unit 318. The imaging system 300 is also connected to an alert device 340 that issues an alert to the driver based on the determination result of the collision determination unit 318. For example, when the collision possibility is high as the determination result of the collision determination unit 318, the control ECU 330 performs vehicle control to avoid collision and reduce damage by braking, returning an accelerator, suppressing engine output, or the like. The alert device 340 alerts a user by sounding an alarm such as a sound, displaying alert information on a screen of a car navigation system or the like, or giving vibration to a seat belt or a steering wheel.

In the present embodiment, the imaging system 300 images the periphery of the vehicle, for example, the front or the rear. FIG. 17B illustrates an imaging system in the case of imaging an image in front of a vehicle (an imaging range 350). The vehicle information acquisition device 320 sends an instruction to the imaging system 300 or the imaging device 310. With such a configuration, the accuracy of distance measurement may be further improved.

In the above description, an example has been described in which control is performed so as not to collide with other vehicles, but the present invention is also applicable to control of automatic driving following other vehicles, control of automatic driving so as not to go out of a lane, and the like. Further, the imaging system is not limited to a vehicle such as a host vehicle, and may be applied to, for example, a movable object (moving device) such as a ship, an aircraft, or an industrial robot. In addition, the present invention may be applied not only to a movable object but also to a wide variety of equipment such as an ITS (intelligent transport systems).

### Eighth Embodiment

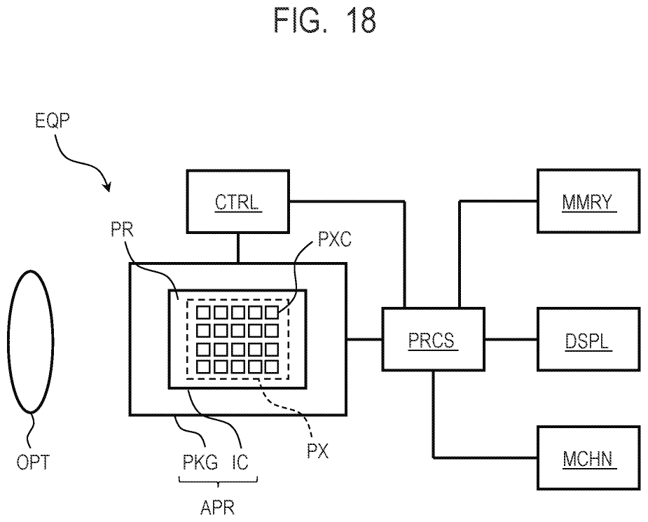

Equipment according to an eighth embodiment of the present invention will be described with reference to FIG. 18. FIG. 18 is a block diagram illustrating a schematic configuration of equipment according to the present embodiment.

FIG. 18 is a schematic diagram illustrating equipment EQP including a photoelectric conversion device APR. The photoelectric conversion device APR has the function of the photoelectric conversion device 100 of any one of the first to fifth embodiments. All or a part of the photoelectric conversion device APR is a semiconductor device IC. The photoelectric conversion device APR of this example may be used, for example, as an image sensor, an AF (Auto Focus) sensor, a photometry sensor, or a distance measurement sensor. The semiconductor device IC includes a pixel area PX in which pixel circuits PXC including photoelectric conversion units are arranged in a matrix. The semiconductor device IC may include a peripheral area PR around the pixel area PX. Circuits other than the pixel circuits may be arranged in the peripheral area PR.

The photoelectric conversion device APR may have a structure (chip stacked structure) in which a first semiconductor chip provided with a plurality of photoelectric conversion units and a second semiconductor chip provided with peripheral circuits are stacked. Each peripheral circuit in the second semiconductor chip may be a column circuit corresponding to a pixel column of the first semiconductor chip. The peripheral circuits in the second semiconductor chip may be matrix circuits corresponding to the pixels or the pixel blocks of the first semiconductor chip. As a connection between the first semiconductor chip and the second semiconductor chip, a through electrode (TSV), an inter-chip interconnection by direct bonding of a conductor such as copper, a connection by micro bumps between chips, a connection by wire bonding, or the like may be adopted.

In addition to the semiconductor device IC, the photoelectric conversion device APR may include a package PKG that accommodates the semiconductor device IC. The package PKG may include a base body to which the semiconductor device IC is fixed, a lid body made of glass or the like facing the semiconductor device IC, and a connection member such as a bonding wire or a bump that connects terminals provided on the base body to terminals provided on the semiconductor device IC.

The equipment EQP may further comprise at least one of an optical device OPT, a control device CTRL, a processing device PRCS, a display device DSPL, a storage device MMRY, and a mechanical device MCHN. The optical device OPT corresponds to the photoelectric conversion device APR as a photoelectric conversion device, and is, for example, a lens, a shutter, or a mirror. The control device CTRL controls the photoelectric conversion device APR, and is, for example, a semiconductor device such as an ASIC. The processing device PRCS processes a signal output from the photoelectric conversion device APR, and constitutes an AFE (analog front end) or a DFE (digital front end). The processing unit PRCS is a semiconductor device such as a central processing unit (CPU) or an ASIC. The display device DSPL may be an EL display device or a liquid crystal display device which displays information (image) obtained by the photoelectric conversion device APR. The storage device MMRY may be a magnetic device or a semiconductor device that stores information (images) obtained by the photoelectric conversion device APR. The storage device MMRY may be a volatile memory such as an SRAM or a DRAM, or a nonvolatile memory such as a flash memory or a hard disk drive. The mechanical device MCHN includes a movable portion or a propulsion portion such as a motor or an engine. In the equipment EQP, a signal output from the photoelectric conversion device APR may be displayed on the display device DSPL, and is transmitted to the outside by a communication device (not illustrated) included in the equipment EQP. Therefore, it is preferable that the equipment EQP further includes a storage device MMRY and a processing device PRCS separately from the storage circuit unit and the arithmetic circuit unit included in the photoelectric conversion device APR.

The equipment EQP illustrated in FIG. 18 may be an electronic device such as an information terminal (for example, a smartphone or a wearable terminal) having a photographing function or a camera (for example, an interchangeable lens camera, a compact camera, a video camera, and a surveillance camera). The mechanical device MCHN in the camera may drive components of the optical device OPT for zooming, focusing, and shutter operation. The equipment EQP may be a transportation device (movable object) such as a vehicle, a ship, or an airplane. The equipment EQP may be a medical device such as an endoscope or a CT scanner.

The mechanical device MCHN in the transport device may be used as a mobile device. The equipment EQP as a transport device is suitable for transporting the photoelectric conversion device APR, or for assisting and/or automating operation (manipulation) by an imaging function. The processing device PRCS for assisting and/or automating operation (manipulation) may perform processing for operating the mechanical device MCHN as a mobile device based on information obtained by the photoelectric conversion device APR.

The photoelectric conversion device APR according to the present embodiment may provide the designer, the manufacturer, the seller, the purchaser, and/or the user with high value. Therefore, when the photoelectric conversion device APR is mounted on the equipment EQP, the value of the equipment EQP may be increased. Therefore, in order to increase the value of the equipment EQP, it is advantageous to determine the mounting of the photoelectric conversion device APR of the present embodiment on the equipment EQP when the equipment EQP is manufactured and sold.

### Modified Embodiments

The present invention is not limited to the above-described embodiments, and various modifications are possible.

For example, an example in which some of the configurations of any of the embodiments are added to other embodiments or an example in which some of the configurations of any of the embodiments are substituted with some of the configurations of the other embodiments is also an embodiment of the present invention.

Although the column circuits 42A and 42B are controlled by the control signals supplied via the same control line in the second to fifth embodiments, the column circuits 42A and 42B may be individually controlled by the control signals supplied via different control lines as in the first embodiment.

In the first to fifth embodiments, one vertical output line 20 is provided in each column of the pixel array unit 10, but the number of vertical output lines 20 provided in each column of the pixel array unit 10 is not limited to one, and may be two or more.

The circuit configurations of the pixels 12, 14, and 16 illustrated in FIG. 2 and FIG. 3 are merely examples, and may be appropriately changed. For example, each of the pixels 12 and 14 may include two or more photoelectric conversion elements. In this case, a plurality of photoelectric conversion elements may share one node FD. Further, a plurality of photoelectric conversion elements may be pupil-division pixels sharing one microlens so that phase difference may be detected. The pixels 12, 14, and 16 do not necessarily have to have the select transistor M4. The capacitance value of the node FD may be switchable.

The imaging systems illustrated in the sixth and seventh embodiments are examples of imaging systems to which the photoelectric conversion device of the present invention may be applied, and imaging systems to which the photoelectric conversion device of the present invention may be applied are not limited to the configurations illustrated in FIG. 16 and FIG. 17A.

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-184524, filed Nov. 18, 2022 which is hereby incorporated by reference herein in its entirety.

What is claimed is:

1. A photoelectric conversion device comprising:
a pixel array unit including a plurality of pixels arranged to form a plurality of columns;
a plurality of column circuits provided corresponding to each of the plurality of columns and to which a pixel signal output from a pixel of the corresponding column is input; and
a plurality of signal lines configured to supply signals to the plurality of column circuits,
wherein the pixel array unit includes
a first region that is provided with a pixel including a photoelectric conversion unit and to which light is incident, and
a second region that is provided with a pixel including no photoelectric conversion units and is shielded from light,
wherein the first region and the second region are defined by columns, and
wherein the plurality of signal lines includes
a first signal line connected to a column circuit corresponding to a column of the first region and not connected to a column circuit corresponding to a column of the second region, and
a second signal line connected to the column circuit corresponding to the column of the second region and not connected to the column circuit corresponding to the column of the first region.

2. The photoelectric conversion device according to claim 1,
wherein the pixel array unit further includes a third region that is provided with a pixel including a photoelectric conversion unit and is shielded from light, and
wherein the plurality of signal lines further includes a third signal line connected to a column circuit corresponding to a column of the third region and not connected to the column circuit corresponding to the column of the first region and the column circuit corresponding to the column of the second region.

3. The photoelectric conversion device according to claim 1,
wherein the pixel array unit further includes a third region that is provided with a pixel including a photoelectric conversion unit and is shielded from light, and
wherein the first signal line is connected to a column circuit corresponding to a column of the third region.

4. The photoelectric conversion device according to claim 1,
wherein each of the plurality of column circuits includes a comparison circuit configured to compare the pixel signal with a reference signal, and
wherein each of the first signal line and the second signal line is a signal line connected to the comparison circuit.

5. The photoelectric conversion device according to claim 4, wherein each of the first signal line and the second signal line is a signal line configured to supply a control signal for controlling a current consumption of the comparison circuit.

6. The photoelectric conversion device according to claim 4, wherein each of the first signal line and the second signal line is a signal line configured to supply a control signal for controlling a reset operation of the comparison circuit.

7. The photoelectric conversion device according to claim 4,
wherein the first signal line is a signal line configured to supply a first reference signal to the comparison circuit, and
wherein the second signal line is a signal line configured to supply a second reference signal different from the first reference signal to the comparison circuit.

8. The photoelectric conversion device according to claim 7, wherein an amplitude of the first reference signal and an amplitude of the second reference signal are different from each other.

9. The photoelectric conversion device according to claim 1,
wherein each of the plurality of column circuit includes a comparison circuit configured to compare the pixel signal with a reference signal, and a switching unit configured to switch the reference signal supplied to the comparison circuit,
wherein each of the first signal line and the second signal line is a signal line configured to supply a control signal for controlling the switching unit.

10. The photoelectric conversion device according to claim 9, wherein each of the plurality of column circuit further includes a buffer circuit connected between a signal line to which the reference signal is supplied and the comparison circuit.

11. The photoelectric conversion device according to claim 1,
wherein each of the plurality of column circuit includes an amplifier circuit configured to amplify the pixel signal, and
wherein each of the first signal line and the second signal line is a signal line configured to supply a control signal for controlling a gain of the amplifier circuit.

12. A photoelectric conversion device comprising:
a pixel array unit including a plurality of pixels arranged to form a plurality of columns;
a plurality of column circuits provided corresponding to each of the plurality of columns and to which a pixel signal output from a pixel of the corresponding column is input; and
a plurality of signal lines configured to supply signals to the plurality of column circuits,
wherein the pixel array unit includes
a first region that is provided with a pixel including a photoelectric conversion unit and to which light is incident,
a second region that is provided with a pixel including no photoelectric conversion units and is shielded from light, and
a third region that is provided with a pixel including a photoelectric conversion unit and is shielded from light,
wherein the first region, the second region and the third region are defined by columns, and
wherein the plurality of signal lines includes
a first signal line connected to a column circuit corresponding to a column of the third region and not connected to a column circuit corresponding to a column of the second region, and
a second signal line connected to the column circuit corresponding to the column of the second region and not connected to the column circuit corresponding to the column of the third region.

13. The photoelectric conversion device according to claim 12,
wherein each of the plurality of column circuit includes a comparison circuit configured to compare the pixel signal with a reference signal, and
wherein each of the first signal line and the second signal line is a signal line connected to the comparison circuit.

14. The photoelectric conversion device according to claim 12,
wherein each of the plurality of column circuit includes a comparison circuit configured to compare the pixel signal with a reference signal, and a switching unit configured switch the reference signal supplied to the comparison circuit, and
wherein each of the first signal line and the second signal line is a signal line configured to supply a control signal for controlling the switching unit.

15. The photoelectric conversion device according to claim 12,
wherein each of the plurality of column circuit includes an amplifier circuit configured to amplify the pixel signal, and
wherein each of the first signal line and the second signal line is a signal line configured to supply a control signal for controlling a gain of the amplifier circuit.

16. A method of driving a photoelectric conversion device including:
a pixel array unit including a plurality of pixels arranged to form a plurality of columns,
a plurality of column circuits provided corresponding to each of the plurality of columns and to which a pixel signal output from a pixel of the corresponding column is input, and
a plurality of signal lines configured to supply signals to the plurality of column circuits,
wherein the pixel array unit includes
a first region that is provided with a pixel including a photoelectric conversion unit and to which light is incident, and
a second region that is provided with a pixel including no photoelectric conversion units and is shielded from light,
wherein the first region and the second region are defined by columns, and
wherein the plurality of signal lines includes
a first signal line connected to a column circuit corresponding to a column of the first region and not connected to a column circuit corresponding to a column of the second region,
a second signal line connected to the column circuit corresponding to the column of the second region and not connected to the column circuit corresponding to the column of the first region,
wherein each of the plurality of column circuit includes a comparison circuit configured to compare the pixel signal with a reference signal, a switching unit configured to switch the reference signal supplied to the comparison circuit, and a buffer circuit connected between a signal line to which the reference signal is supplied and the comparison circuit, and
wherein each of the first signal line and the second signal line is a signal line configured to supply a control signal for controlling the switching unit, the method comprising:
outputting, when an AD conversion of the pixel signal of a reset level is performed, a control signal for selecting a first reference signal to the switching unit of the column circuit corresponding to the column of the first region via the first signal line, and a control signal for selecting the first reference signal to the switching unit of the column circuit corresponding to the column of the second region via the second signal line;
outputting, when an AD conversion of the pixel signal of a light signal level is performed and an object is low luminance, a control signal for selecting the first reference signal to the switching unit of the column circuit corresponding to the column of the first region via the first signal line, and a control signal for selecting a second reference signal having an amplitude larger than the first reference signal to the switching unit of the column circuit corresponding to the column of the second region via the second signal line; and
outputting, when an AD conversion of the pixel signal of a light signal level is performed and an object is high luminance, a control signal for selecting the second reference signal to the switching unit of the column circuit corresponding to the column of the first region via the first signal line, and a control signal for selecting the second reference signal to the switching unit of the column circuit corresponding to the column of the second region via the second signal line.

17. An imaging system comprising:
the photoelectric conversion device according to claim 1; and
a signal processing device configured to process a signal output from the photoelectric conversion device.

18. A movable object comprising:
the photoelectric conversion device according to claim 1; and
a distance information acquisition unit configured to acquire distance information to an object from a parallax image based on a signal from the photoelectric conversion device; and
a control unit configured to control the movable object based on the distance information.

19. Equipment comprising:
the photoelectric conversion device according to claim 1, and
at least one of
an optical device corresponding to the photoelectric conversion device,
a control device configured to control the photoelectric conversion device,
a processing device configured to process a signal output from the photoelectric conversion device,
a mechanical device that is controlled based on information obtained by the photoelectric conversion device,
a display device configured to display information obtained by the photoelectric conversion device, and
a storage device configured to store information obtained by the photoelectric conversion device.
